(19) United States
(12) Patent Application Publication
(10) Pub. No.: US 2026/0223377 A1
(43) Pub. Date: Jul. 30, 2026

(54) SEMICONDUCTOR MEMORY DEVICE AND MANUFACTURING METHOD THEREOF

(71) Applicant: SK hynix Inc., Icheon-si Gyeonggi-do (KR)

(72) Inventor: Eun Seok CHOI, Icheon-si Gyeonggi-do (KR)

(73) Assignee: SK hynix Inc., Icheon-si Gyeonggi-do (KR)

(21) Appl. No.: 19/630,030

(22) Filed: Mar. 26, 2026

Related U.S. Application Data
(63) Continuation-in-part of application No. 17/853,196, filed on Jun. 29, 2022.

(30) Foreign Application Priority Data
Feb. 3, 2022 (KR) 10-2022-0014127

(51) Int. Cl. H10B 80/00; H10B 41/27; H10B 41/35; H10B 43/27; H10B 43/35; H10W 80/00; H10W 90/00; H10W 90/26

(52) U.S. Cl. CPC H10B 80/00; H10B 41/27; H10B 41/35; H10B 43/27; H10B 43/35; H10W 80/312; H10W 90/26; H10W 90/792

(57) ABSTRACT

A semiconductor memory device of the technology, including: a lower structure; a first stacked structure; and a second stacked structure, wherein the first stacked structure includes at least one lower cell plug pattern extending in a vertical direction and a lower slit pattern extending in the vertical direction, and wherein the first stacked structure further includes: a first conductive pattern; a second conductive pattern over the first conductive pattern, wherein the second conductive pattern includes a first portion and a second portion; and a contact structure connected to the first conductive pattern and disposed between the first and second portions of the second conductive pattern.

### CROSS-REFERENCE TO RELATED APPLICATION

The present application is a continuation-in-part of U.S. Application No. 17/853,196 filed on June 29, 2022, which claims priority under 35 U.S.C. § 119(a) to Korean patent application number 10-2022-0014127, filed on February 3, 2022, in the Korean Intellectual Property Office, the entire disclosure of which is incorporated by reference herein.

### BACKGROUND

### 1. Technical Field

Various embodiments relate generally to an electronic device, and more particularly, to a semiconductor memory device having a vertical channel structure and a method of manufacturing the semiconductor memory device.

### 2. Related Art

Recently, a paradigm for a computer environment has changed into ubiquitous computing which makes a computer system available at any time from any location. Therefore, the use of portable electronic devices such as cellular phones, digital cameras, and laptop computers, has surged. A portable electronic device generally uses a memory system including a semiconductor memory device, i.e., a data storage device. The data storage device may serve as a main storage device or an auxiliary storage device of the portable electronic device.

The data storage device using the semiconductor memory device has excellent stability and durability since it does not have any mechanical driving parts. In addition, the data storage device provides quick access to information and has low power consumption. Examples of the data storage device of the memory system having these advantages may include a universal serial bus (USB) memory device, a memory card having various interfaces, and a solid state drive (SSD).

Semiconductor memory devices may be classified as volatile memory devices or nonvolatile memory devices.

Nonvolatile memory devices operate at relatively low write and read speeds, but they may retain stored data in the absence of supplied power. Therefore, nonvolatile memory devices may be used when there is the need for storing data which should be retained regardless of a supply of power. Examples of the nonvolatile memory devices may include Read Only Memory (ROM), Mask ROM (MROM), Programmable ROM (PROM), Erasable Programmable ROM (EPROM), Electrically Erasable Programmable ROM (EEPROM), flash memory, Phase-change Random Access Memory (PRAM), Magnetic RAM (MRAM), Resistive RAM (RRAM), and Ferroelectric RAM (FRAM). Flash memory may be classified as NOR-type memory or NAND-type memory.

### SUMMARY

Various embodiments are directed to a semiconductor memory device and a manufacturing method thereof which facilitate manufacturing processes by performing an etch process for forming a cell plug and a slit and a process of filling a conductive material therein at the same time during a process of forming a contact plug passing through a stacked structure.

According to some embodiments, a semiconductor memory device may include a lower structure including a cell region and a contact region; a first stacked structure including a first portion over the cell region of the lower structure and a second portion over the contact region of the lower structure; and a second stacked structure stacked over the first portion of the first stacked structure, wherein the first stacked structure includes at least one lower cell plug pattern extending in a vertical direction and a lower slit pattern extending in the vertical direction, wherein the second stacked structure includes at least one upper cell plug pattern extending in the vertical direction and directly contacting an upper surface of the at least one lower cell plug pattern, and an upper slit pattern extending in the vertical direction and directly contacting an upper surface of the lower slit pattern, wherein a lower surface of the upper slit pattern contacting the upper surface of the lower slit pattern has a lower critical dimension than the upper surface of the lower slit pattern, and wherein the first stacked structure further includes: a first conductive pattern; a second conductive pattern over the first conductive pattern, wherein the second conductive pattern includes a first portion and a second portion; and a contact structure connected to the first conductive pattern and disposed between the first and second portions of the second conductive pattern.

According to some embodiments, a semiconductor memory device may include a lower structure including a cell region and a contact region; a first stacked structure including a first portion over the cell region of the lower structure and a second portion over the contact region of the lower structure; and a second stacked structure stacked over the first portion of the first stacked structure, wherein the first stacked structure includes at least one lower cell plug pattern extending in a vertical direction and a lower slit pattern extending in the vertical direction, wherein the second stacked structure includes at least one upper cell plug pattern extending in the vertical direction and directly contacting an upper surface of the at least one lower cell plug pattern, and an upper slit pattern extending in the vertical direction and directly contacting an upper surface of the lower slit pattern, wherein a lower surface of the upper slit pattern contacting the upper surface of the lower slit pattern has a lower critical dimension than the upper surface of the lower slit pattern, wherein the first stacked structure further includes: a first conductive pattern; a second conductive pattern over the first conductive pattern; a contact structure connected to the first conductive pattern; and a contact spacer between the second conductive pattern and the contact structure, and wherein the contact spacer surrounds the first conductive pattern.

### BRIEF DESCRIPTION OF THE DRAWINGS

FIG. 1 is a block diagram illustrating a semiconductor memory device according to an embodiment of the present disclosure;

FIG. 2 is a circuit diagram illustrating a memory cell array of FIG. 1;

FIG. 3 is a perspective view illustrating a semiconductor memory device according to embodiments of the present disclosure;

FIG. 4 is a cross-sectional view illustrating an embodiment of a memory cell array shown in FIG. 1;

FIGS. 5A to 5G, 6, 7, 8A, and 8B are cross-sectional views illustrating a method of manufacturing a semiconductor memory device according to an embodiment of the present disclosure;

FIG. 9 is a cross-sectional view illustrating another embodiment of a memory cell array shown in FIG. 1;

FIG. 10 is a block diagram illustrating the configuration of a memory system according to an embodiment of the present disclosure; and

FIG. 11 is a block diagram illustrating the configuration of a computing system according to an embodiment of the present disclosure.

FIGS. 12A and 12B are diagrams illustrating a semiconductor device according to some embodiments.

FIGS. 13A and 13B are diagrams illustrating semiconductor memory devices according to some embodiments.

FIG. 14 is a diagram illustrating a semiconductor memory device according to some embodiments.

FIGS. 15A and 15B are diagrams illustrating semiconductor memory devices according to some embodiments.

FIGS. 16A and 16B are diagrams illustrating semiconductor memory devices according to some embodiments.

FIG. 17 is a diagram illustrating a semiconductor memory device according to some embodiments.

FIG. 18 is a diagram illustrating a semiconductor memory device according to some embodiments.

FIG. 19 is a diagram illustrating a semiconductor memory device according to some embodiments.

FIG. 20 is a diagram illustrating a semiconductor memory device according to some embodiments.

FIG. 21 is a diagram illustrating a semiconductor memory device according to some embodiments.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, embodiments of the present disclosure will be described in detail with reference to the accompanying drawings in order for those skilled in the art to be able to readily implement the technical spirit of the present disclosure.

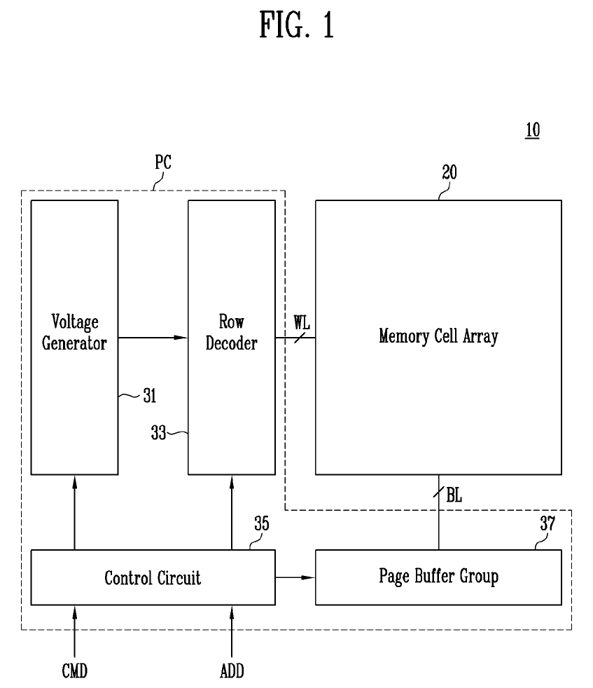

FIG. 1 is a block diagram illustrating a semiconductor memory device 10 according to an embodiment of the invention.

Referring to FIG. 1, the semiconductor memory device 10 may include a peripheral circuit PC and a memory cell array 20.

The peripheral circuit PC may be configured to control a program operation of storing data in the memory cell array 20, a read operation of outputting data stored in the memory cell array 20, and an erase operation of erasing data stored in the memory cell array 20.

According to an embodiment, the peripheral circuit PC may include a voltage generator 31, a row decoder 33, a control circuit 35, and a page buffer group 37.

The memory cell array 20 may include a plurality of memory blocks. The memory cell array 20 may be coupled to the row decoder 33 through word lines WL and to the page buffer group 37 through bit lines BL.

The control circuit 35 may control the voltage generator 31, the row decoder 33, and the page buffer group 37 in response to a command CMD and an address ADD.

The voltage generator 31 may generate various operating voltages such as an erase voltage, a ground voltage, a program voltage, a verify voltage, a pass voltage, and a read voltage which are used for a program operation, a read operation, and an erase operation in response to control of the control circuit 35.

The row decoder 33 may select a memory block in response to control of the control circuit 35. The row decoder 33 may be configured to apply the operating voltages to the word lines WL coupled to a selected memory block.

The page buffer group 37 may be coupled to the memory cell array 20 through the bit lines BL. The page buffer group 37 may temporarily store data received from an input and output circuit (not shown) during a program operation in response to control of the control circuit 35. The page buffer group 37 may sense voltages or currents in the bit lines BL during a read operation or a verify operation in response to control of the control circuit 35. The page buffer group 37 may select the bit lines BL in response to control of the control circuit 35.

Structurally, the memory cell array 20 may overlap part of the peripheral circuit PC.

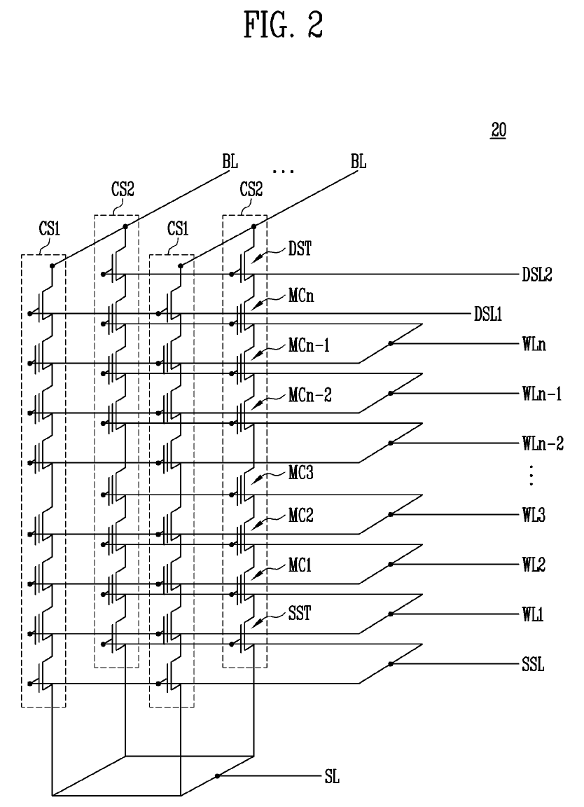

FIG. 2 is a circuit diagram illustrating the memory cell array 20 of FIG. 1.

Referring to FIG. 2, the memory cell array 20 may include a plurality of cell strings CS1 and CS2 which are coupled between a source line SL and the plurality of bit lines BL. The plurality of cell strings CS1 and CS2 may be commonly coupled to a plurality of word lines WL1 to WLn.

Each of the plurality of cell strings CS1 and CS2 may include at least one source select transistor SST coupled to the source line SL, at least one drain select transistor DST coupled to the bit line BL, and a plurality of memory cells MC1 to MCn coupled in series between the source select transistor SST and the drain select transistor DST.

Gates of the plurality of memory cells MC1 to MCn may be coupled to the plurality of word lines WL1 to WLn which are separated and stacked on top of each other. The plurality of word lines WL1 to WLn may be arranged between a source select line SSL and at least two drain select lines DSL1 and DSL2. At least two drain select lines DSL1 and DSL2 may be separated from each other at the same level.

A gate of the source select transistor SST may be coupled to the source select line SSL. A gate of the drain select transistor DST may be coupled to a drain select line corresponding to the gate of the drain select transistor DST.

The source line SL may be coupled to a source of the source select transistor SST. A drain of the drain select transistor DST may be coupled to a bit line corresponding to the drain of the drain select transistor DST.

The plurality of cell strings CS1 and CS2 may be divided into string groups coupled to at least two drain select lines DSL1 and DSL2, respectively. Cell strings coupled to the same word line and the same bit line may be controlled independently of each other by different drain select lines. In addition, cell strings coupled to the same drain select line may be controlled independently of each other by different bit lines.

According to an embodiment, at least two drain select lines DSL1 and DSL2 may include a first drain select line DSL1 and a second drain select line DSL2. The plurality of cell strings CS1 and CS2 may include a first cell string CS1 of the first string group coupled to the first drain select line DSL1 and a second cell string CS2 of the second string group coupled to the second drain select line DSL2.

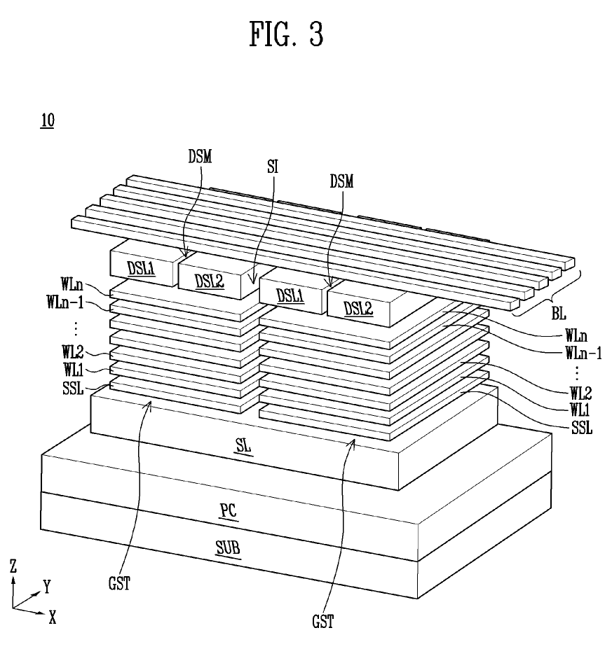

FIG. 3 is a perspective view illustrating the semiconductor memory device 10 according to embodiments of the present disclosure.

Referring to FIG. 3, the semiconductor memory device 10 may include the peripheral circuit PC which is disposed on a substrate SUB and gate stacks GST which overlap the peripheral circuit PC.

Each of the gate stacks GST may include the source select line SSL, the plurality of word lines WL1 to WLn, and the two or more drain select lines DSL1 and DSL2 which are separated from each other by a separation structure DSM.

The source select line SSL and the plurality of word lines WL1 to WLn may extend in a first direction X and a second direction Y and be formed as a flat plate in parallel with a top surface of the substrate SUB. The first direction X may refer to a direction of an X axis in a XYZ coordinate system, and the second direction Y may refer to a direction of a Y axis in the XYZ coordinate system.

The plurality of word lines WL1 to WLn may be separated and stacked on top of each other in a third direction Z. The third direction Z may refer to a direction of a Z axis in the XYZ coordinate system. The plurality of word lines WL1 to WLn may be arranged between at least two drain select lines DSL1 and DSL2 and the source select line SSL.

The gate stacks GST may be separated from each other by a slit SI. The separation structure DSM may be shorter than the slit SI in the third direction Z and overlap the plurality of word lines WL1 to WLn.

Each of the separation structure DSM and the slit SI may extend in a straight line, a zig-zag manner, or a wave form. A width of the separation structure DSM and the slit SI may vary according to embodiment.

According to an embodiment, the source select line SSL may be arranged closer to the peripheral circuit PC than the two or more drain select lines DSL1 and DSL2.

The semiconductor memory device 10 may include the source line SL which is arranged between the gate stacks GST and the peripheral circuit PC and the bit lines BL which are more distant from the peripheral circuit PC than the source line SL. The gate stacks GST may be arranged between the plurality of bit lines BL and the source line SL.

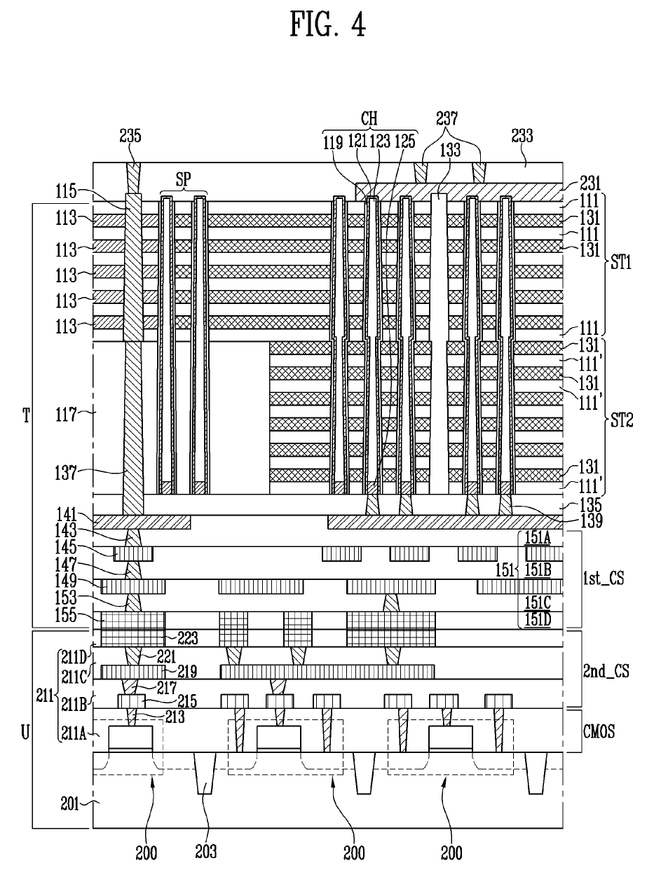

FIG. 4 is a cross-sectional view illustrating an embodiment of the memory cell array 20 shown in FIG. 1.

Referring to FIG. 4, the memory cell array 20 may include a lower structure U and an upper structure T that are bonded to each other.

The upper structure T may include a first gate stack ST1 and a second gate stack ST2 which are stacked on each other in a vertical direction, channel structures CH and an insulating pattern 133 which pass through the first gate stack ST1 and the second gate stack ST2 in the vertical direction, and a bit line 141 and a first connection structure 1st_CS which are arranged under the second gate stack ST2.

A region where the first gate stack ST1 and the second gate stack ST2 are stacked on top of each other and the channel structures CH pass through the first gate stack ST1 and the second gate stack ST2 may be defined as a cell region.

A critical dimension of the insulating pattern 133 which passes through the first gate stack ST1 and the second gate stack ST2 may be variable at a boundary region between the first gate stack ST1 and the second gate stack ST2. For example, a critical dimension of the insulating pattern 133 which passes through a lowermost surface of the first gate stack ST1 may be greater than that of the insulating pattern 133 which passes through an uppermost surface of the second gate stack ST2.

In addition, a critical dimension of the channel structure CH which passes through the first gate stack ST1 and the second gate stack ST2 may be variable at the boundary region between the first gate stack ST1 and the second gate stack ST2. For example, the critical dimension of the channel structure CH which passes through the lowermost surface of the first gate stack ST1 may be greater than that of the channel structure CH which passes through the uppermost surface of the second gate stack ST2.

In the cell region, the first gate stack ST1 and the second gate stack ST2 may include interlayer insulating layers 111 and 111’ and conductive patterns 131 which are stacked alternately with each other in the vertical direction. Each of the conductive patterns 131 may include various conductive materials such as a doped silicon layer, a metal layer, a metal silicide layer, and a barrier layer, and may include two or more types of conductive materials. For example, each of the conductive patterns 131 may include tungsten and a titanium nitride (TiN) layer which surrounds the surface of tungsten. Tungsten is a low-resistance metal and may reduce the resistance of the conductive patterns 131. The titanium nitride (TiN) layer may be a barrier layer and prevent direct contact between the interlayer insulating layers 111 and 111’.

A conductive pattern adjacent to the bit line 141, among the conductive patterns 131, may serve as the drain select line DSL1 or DSL2 as shown in FIG. 2. According to another embodiment, two or more conductive patterns which are adjacent to the bit line 141 and stacked on top of each other may serve as drain select lines. A conductive pattern adjacent to a source layer 231, among the conductive patterns 131, may serve as the source select line SSL as shown in FIG. 2. According to another embodiment, two or more conductive patterns which are adjacent to the source layer 231 and stacked on top of each other may serve as source select lines. Conductive patterns which are adjacent to each other in a vertical direction and are arranged between a drain select line and a source select line may serve as the word lines WL1 to WLn as shown in FIG. 2.

The channel structure CH may pass through the first gate stack ST1 and the second gate stack ST2 in the vertical direction. The channel structure CH may be formed as a hollow type. The channel structure CH may include a core insulating layer 123 which fills a central area thereof, a doped semiconductor layer 125 which is located under the core insulating layer 123, a channel layer 121 which surrounds sidewall surfaces of the core insulating layer 123 and the doped semiconductor layer 125 and an upper surface of the core insulating layer 123, and a memory layer 119 which surrounds an outer wall of the channel layer 121. The channel layer 121 may serve as a channel region of a cell string corresponding thereto. The channel layer 121 may include a semiconductor material. The memory layer 119 may include a tunnel isolation layer which surrounds the outer wall of the channel layer 121, a data storage layer which surrounds an outer wall of the tunnel isolation layer, and a blocking insulating layer which surrounds an outer wall of the data storage layer.

The bit line 141 may be arranged under the second gate stack ST2. The bit line 141 may be coupled to the channel structure CH through contacts 139 which pass through an insulating layer 135. The bit line 141 may be separated from a second substrate 201 by a first insulation structure 151 and a second insulation structure 211.

The first connection structure 1st_CS may include the first insulation structure 151 and first connection structures 143, 145, 147, 149, 153, and 155 formed in the first insulation structure 151. The first connection structures 143, 145, 147, 149, 153, and 155 may include various conductive patterns. The first insulation structure 151 may include two or more insulating layers 151A to 151D which are stacked on top of each other between the bit line 141 and the second insulation structure 211.

The source layer 231, a contact 235 for a contact plug, and a contact 237 for a source line may be arranged over the upper structure T. The source layer 231 may electrically and physically contact the channel layers 121 of the channel structures CH which protrude above the first gate stack ST1. The source layer 231 and the first gate stack ST1 may be covered by an insulating layer 233. The contact 237 for a source line may pass through the insulating layer 233 to be coupled to the source layer 231.

In a contact region adjacent to the cell region, the first gate stack ST1 and an interlayer insulating layer 117 may be stacked on each other. A region where the first gate stack ST1 and the interlayer insulating layer 117 are stacked on each other and a plurality of support structures SP and contact plugs 115 and 137 pass through the first gate stack ST1 and the interlayer insulating layer 117 may be defined as a contact region. The interlayer insulating layer 117 may be disposed under the first gate stack ST1. The upper structure T may include the plurality of support structures SP which pass through the interlayer insulating layer 117. The plurality of support structures SP may include the same components as the channel structures. In addition, a stacked structure which includes the interlayer insulating layers 111 and 113 stacked alternately with each other and the interlayer insulating layer 117 which is formed under the stacked structure may be arranged in the contact region. A first conductive layer 115 and a second conductive layer 137 which pass through the interlayer insulating layers 111, 113, and 117 in the vertical direction may be included in the contact region. A height of the boundary surface between the interlayer insulating layer 117 and the interlayer insulating layer 111 may be the same as that of the boundary surface between the first gate stack ST1 and the second gate stack ST2 in the cell region. The first conductive layer 115 and the second conductive layer 137 may be electrically coupled to each other and defined as a contact plug. A critical dimension of the first conductive layer 115 may be greater than that of the second conductive layer 137 in a region where the first conductive layer 115 and the second conductive layer 137 contact each other.

The lower structure U may include a CMOS circuit structure CMOS which includes a plurality of transistors 200 formed on the substrate SUB and a second connection structure 2nd_CS which is formed on the CMOS circuit structure CMOS. An isolation layer 203 may be disposed in the substrate SUB and separate junctions of the plurality of transistors 200 from each other.

The second connection structure 2nd_CS may include a second insulation structure 211 which is formed on the substrate SUB and second connection structures 213, 215, 217, 219, 221, and 223 which are formed in the second insulation structure 211. Each of the second connection structures 213, 215, 217, 219, 221, and 223 may be embedded in the second insulation structure 211. The second insulation structure 211 may include two or more insulating layers 211A to 211D which are stacked sequentially.

The upper structure T and the lower structure U may be adhered to each other by a bonding process. For example, exposed conductive patterns 155 of the first connection structure 1st_CS of the upper structure T and exposed conductive patterns 223 of the second connection structure 2nd_CS of the lower structure U may face each other and be bonded to each other. The conductive patterns 155 and the conductive patterns 223 may be defined as bonding metal.

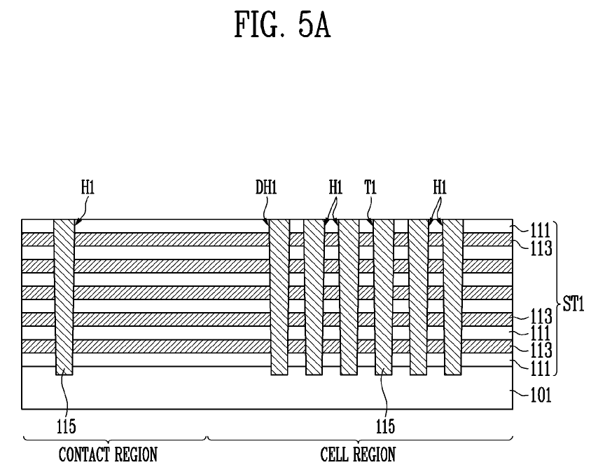

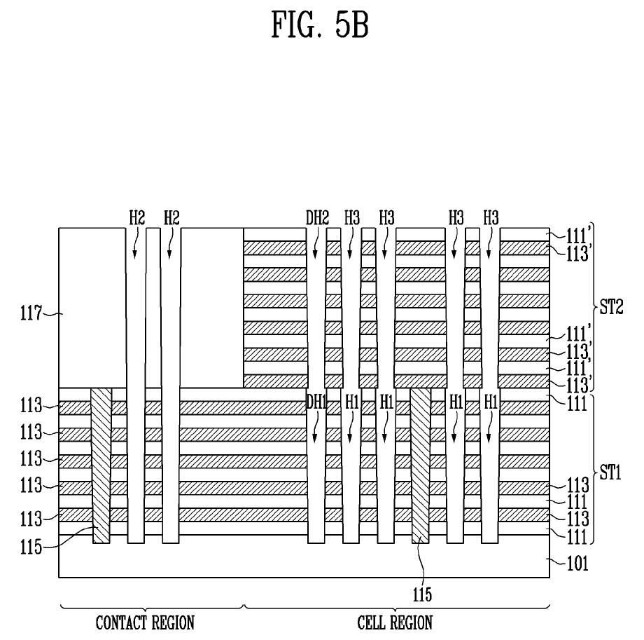

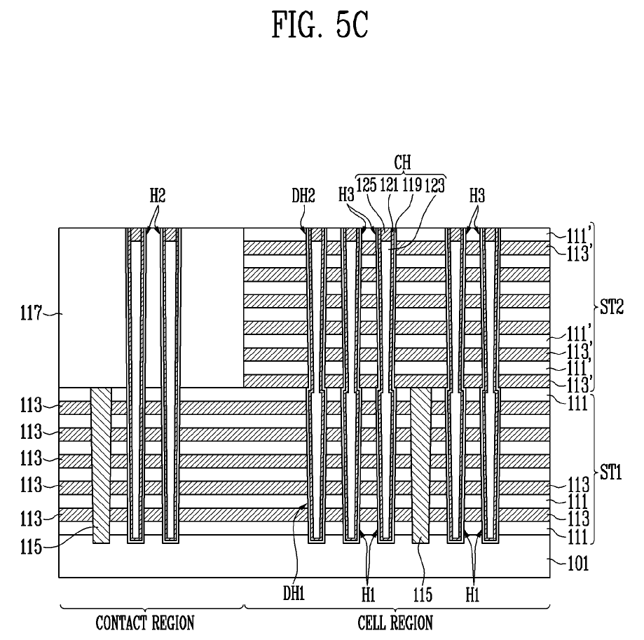

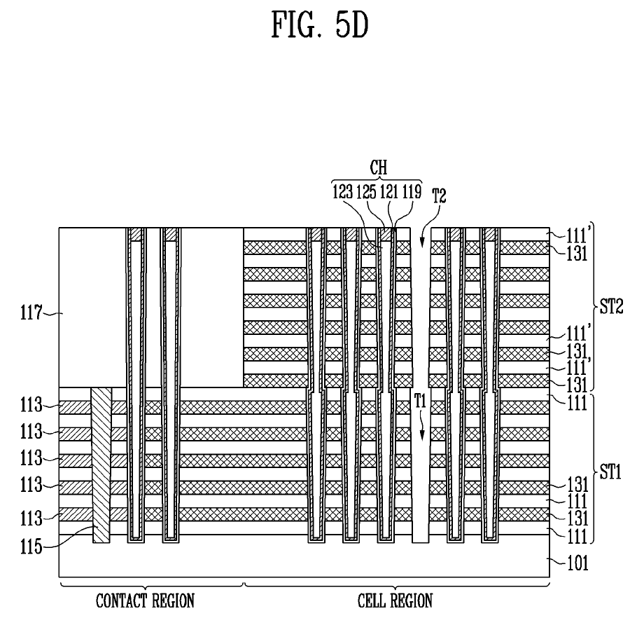

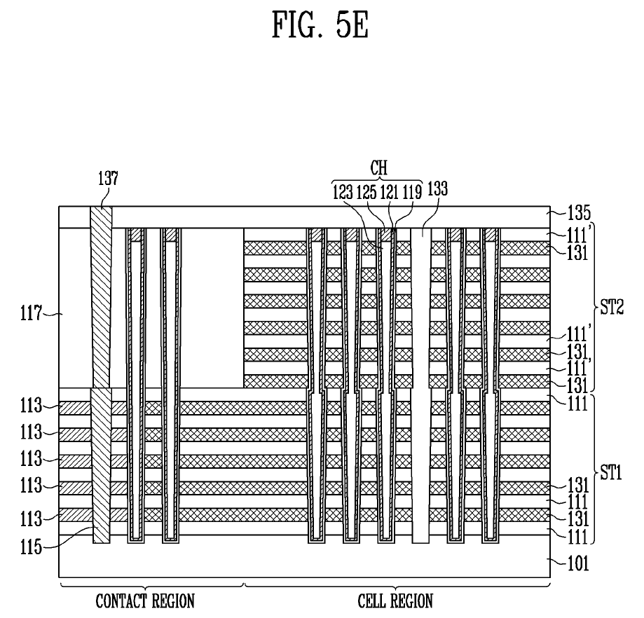

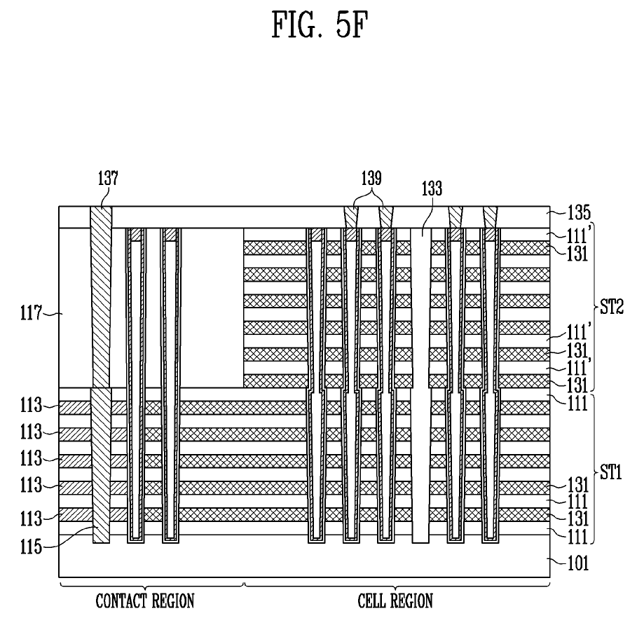

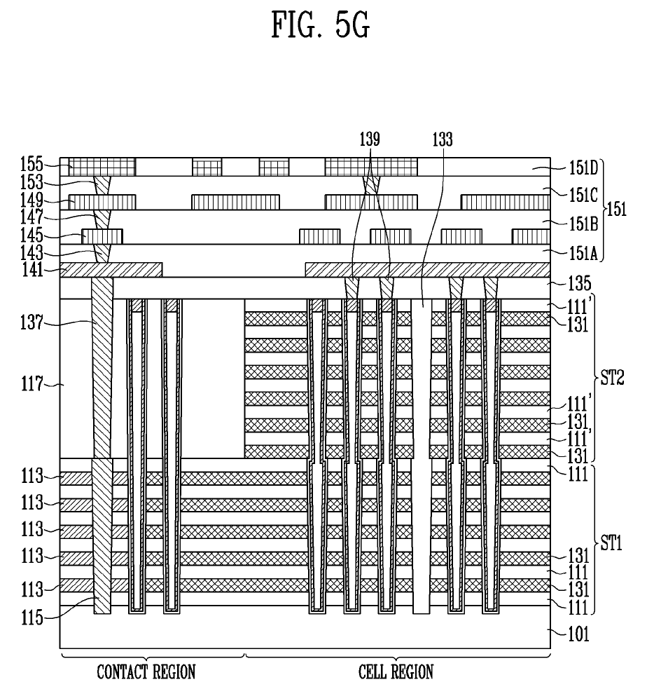

FIGS. 5A to 5G, 6, 7, 8A, and 8B are cross-sectional views illustrating a method of manufacturing the semiconductor memory device 10 according to an embodiment of the present disclosure.

FIGS. 5A to 5G are cross-sectional views illustrating processes of forming a memory cell array, a first wiring array and first connection structures on a first substrate.

Referring to FIG. 5A, a first stacked structure ST1 may be formed by stacking first material layers 111 and second material layers 113 alternately with each other on a first substrate 101.

The first substrate 101 may include a contact region and a cell region. The contact region may refer to a region where a contact plug is formed. The cell region may refer to a region where cell plugs are formed.

The first substrate 101 may include a material which has a different etch rate from those of the first material layers 111 and the second material layers 113. For example, the first substrate 101 may include silicon.

According to an embodiment, the first material layers 111 may include an insulating material for the interlayer insulating layers 111 as described above with reference to FIG. 4. The second material layers 113 may include a material which has a different etch rate from that of the first material layers 111. For example, the first material layers 111 may include silicon oxide, and the second material layers 113 may include silicon nitride. FIGS. 5B to 5G illustrate an embodiment in which the first material layers 111 include an insulating material and the second material layers 113 include sacrificial layers. However, the invention is not limited thereto. The physical properties of the first material layers 111 and the second material layers 113 may vary. For example, the first material layers 111 may include an insulating material for the interlayer insulating layers 111 as described above with reference to FIG. 4, and the second material layers 113 may include a conductive material for the conductive patterns 131 as described above with reference to FIG. 4.

By performing an etch process, a plurality of first holes H1 and a first dummy hole DH1 may be formed through the first stacked structure ST1. For example, the first hole H1 which passes through the first stacked structure ST1 in the contact region may be provided to form a contact plug, and the first holes H1 which pass through the first stacked structure ST1 in the cell region may be provided to form cell plugs. The first dummy hole DH1 which passes through the first stacked structure ST1 in the cell region may be provided to form a dummy cell plug.

During the above-described etch process, a first trench T1 which passes through the first stacked structure ST1 may also be formed. The first trench T1 may pass through the first stacked structure ST1 in the cell region and extend in a horizontal direction with respect to the first substrate 101.

The first holes H1 and the first dummy hole DH1 may pass through the first stacked structure ST1 and partially extend into the first substrate 101.

The first holes H1 and the first dummy hole DH1 may be filled with the first conductive layer 115. The first conductive layer 115 may include a diffusion barrier layer and a conductive layer. For example, the diffusion barrier layer may include a titanium nitride (TiN) layer and the conductive layer may include a low resistance material. The diffusion barrier layer may be formed to surround the surface of the conductive layer.

Referring to FIG. 5B, the second stacked structure ST2 may be formed on the first stacked structure ST1 and the first conductive layer 115. The second stacked structure ST2 may be formed by stacking third material layers 113’ and fourth material layers 111’ alternately with each other. For example, the third material layers 113’ may be the same as the second material layers 113 of the first stacked structure ST1, and the fourth material layers 111’ may be the same as the first material layers 111 of the first stacked structure ST1.

Subsequently, the second stacked structure ST2 may be removed from the contact region. A process of removing the second stacked structure ST2 from the contact region may be performed at the same time as a slimming process of forming the second stacked structure ST2 in the cell region to have a stepped structure.

The interlayer insulating layer 117 may be formed on the first stacked structure ST1 in the contact region.

By performing an etch process, second holes H2 may be formed through the interlayer insulating layer 117 and the first stacked structure ST1 in the contact region, a second dummy hole DH2 may be formed through the second stacked structure ST2 in the cell region to expose the first conductive layer 115 of FIG. 5A which fills the first dummy hole DH1, and third holes H3 may be formed through the second stacked structure ST2 in the cell region to expose the first conductive layer 115 of FIG. 5A which fills the first holes H1.

The first conductive layer filling the exposed first dummy hole DH1 and the first conductive layer filling the first holes H1 may be removed.

During the etch process of the second holes H2 and the process of removing the first conductive layer filling the first dummy hole DH1 and the first conductive layer filling the first holes H1, the first conductive layer 115 passing through the first stacked structure ST1 in the contact region and the first conductive layer 115 passing through the first stacked structure ST1 in the cell region may serve as support structures.

Referring to FIG. 5C, the channel structure CH may be formed in the second holes H2 in the contact region, the first dummy hole DH1 and the second dummy hole DH2 in the cell region, and the first holes H1 and the third holes H3 in the cell region.

For example, the memory layer 119, the channel layer 121, the core insulating layer 123, and the doped semiconductor layer 125 may be formed in the second holes H2, the first dummy hole DH1, the second dummy hole DH2, the first holes H1, and the third holes H3.

According to an embodiment, the memory layer 119 in the form of a liner may be formed along inner sidewalls of the second holes H2, the first dummy hole DH1, the second dummy hole DH2, the first holes H1, and the third holes H3. The memory layer 119 may be provided by forming a blocking insulating layer, a data storage layer, and a tunnel isolation layer sequentially along inner sidewalls of the second holes H2, the first dummy hole DH1, the second dummy hole DH2, the first holes H1, and third holes H3.

The channel structure CH may be formed by forming the channel layer 121 on a surface of the memory layer 119. The channel layer 121 may include doped polysilicon.

According to an embodiment, the channel layer 121 may be in the form of a liner, and central regions of the second holes H2, the first dummy hole DH1, the second dummy hole DH2, the first holes H1, and third holes H3 may include portions which are not filled with the channel layer 121. When the channel layer 121 is in the form of a liner, forming the channel structure CH may include a process of filling central regions of the second holes H2, the first dummy hole DH1, and the second dummy hole DH2 in the surface of the channel layer 121 with the core insulating layer 123, and a process of etching a portion of the upper part of the core insulating layer 123 to define a recess region in a portion of a central region and filling the recess region with the doped semiconductor layer 125. The core insulating layer 123 may include oxides and the doped semiconductor layer 125 may include conductivity type dopants. The conductivity type dopant may include an n type dopant for a junction. The conductivity type dopant may include a counter-doped p type dopant.

The channel structure CH which fills the second holes H2 in the contact region and the channel structure CH which fills the first and second dummy holes DH1 and DH2 in the cell region may serve as support structures for preventing patterns from collapsing or tilting during the etch process of the first and second stacked structures ST1 and ST2.

Referring to FIG. 5D, a second trench T2 through which the first conductive layer 115 of FIG. 5C in the first trench T1 is exposed may be formed by etching the second stacked structure ST2 in the cell region. The second trench T2 may extend in the same direction as the first trench T1. The first conductive layer exposed in the first trench T1 may be removed. The first trench T1 and the second trench T2 may be defined as slits. The slits T1 and T2 may correspond to the slit SI of FIG. 3.

Horizontal spaces may be formed by removing the second material layers 113 of FIG. 5C and the third material layers 113’ of FIG. 5C from the cell region exposed through the slits T1 and T2. The horizontal spaces from which the second material layers 113 of FIG. 5C and the third material layers 113’ of FIG. 5C are removed may be filled with the conductive patterns 131. The conductive patterns 131 may serve as at least one drain select line, a plurality of word lines, and at least one source select line. The conductive patterns 131 may form sidewalls of the channel structures CH.

The first stacked structure ST1 in which the first material layers 111 and the conductive patterns 131 are stacked alternately with each other may be defined as a first gate stack. The second stacked structure ST2 in which the fourth material layers 111’ and the conductive patterns 131 are stacked alternately with each other may be defined as a second gate stack. Therefore, the channel structures CH may pass through the first and second gate stacks, and the slits T1 and T2 may pass through the first and second gate stacks.

The second material layers 113 may remain by controlling an etch amount and an etch time during the etch process of removing the second material layers 113 of FIG. 5C and the third material layers 113’ of FIG. 5C which are exposed through the above-described slits T1 and T2. For example, the second material layers 113 which surround the sidewall of the first conductive layer 115 in the contact region may remain.

Referring to FIG. 5E, the insulating pattern 133 may be formed by filling the slits T1 and T2 of FIG. 5D with an insulating material. The insulating layer 135 may be formed on the second stacked structure ST2. By etching the insulating layer 135 and the interlayer insulating layer 117 in the contact region, a hole through which the first conductive layer 115 is exposed may be formed, and the hole may be filled with a conductive material to form the second conductive layer 137 which is electrically and physically coupled to the first conductive layer 115. The second conductive layer 137 may include a diffusion barrier layer and a conductive layer. For example, the diffusion barrier layer may include a titanium nitride (TiN) layer, and the conductive layer may include a low resistance material such as tungsten (W). The diffusion barrier layer may be formed to surround the surface of the conductive layer. The first conductive layer 115 and the second conductive layer 137 may be defined as a contact plug.

Referring to FIG. 5F, by etching a portion of the insulating layer 135 in the cell region, contact holes through which an upper part of the channel structure CH serving as cell plugs is opened may be formed. The contacts 139 may be formed by filling the contact holes with a conductive material.

According to another embodiment, the process of forming the contacts 139 may be performed at the same time as the process of forming the second conductive layer 137 as described above with FIG. 5E is performed.

Referring to FIG. 5G, a first wiring array 141 may be formed on the insulating layer 135 in the cell region. The first wiring array 141 may be a bit line which is coupled to the contacts 139. A second wiring array 141 may be formed on the insulating layer 135 in the contact region. The second wiring array 141 may be electrically and physically coupled to the second conductive layer 137. The first insulation structure 151 which covers the first and second wiring arrays 141 may then be formed. The first insulation structure 151 may include two or more insulating layers 151A to 151D. The first connection structures 145, 149, and 155 may be embedded in the first insulation structure 151. The first connection structures 145, 149, and 155 may be electrically coupled to each other through contacts, for example, the contacts 143, 147, and 153.

The first connection structures 145, 149, and 155 may include a first bonding metal 155 which has a surface exposed to the outside of the first insulation structure 151.

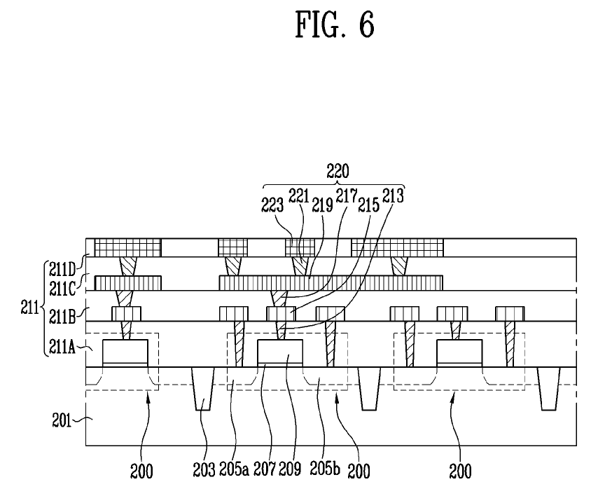

FIG. 6 is a cross-sectional diagram illustrating processes of forming a CMOS circuit and second connection structures on a second substrate.

Referring to FIG. 6, a plurality of transistors 200 which constitute a complementary metal oxide semiconductor (CMOS) circuit may be formed on the second substrate 201.

For example, the second substrate 201 may be a bulk silicon substrate, a silicon-on-insulator substrate, a germanium substrate, a germanium-on-insulator substrate, a silicon-germanium substrate, or an epitaxial layer formed by a selective epitaxial growth method.

Each of the transistors 200 may be formed in an active region of the second substrate 201 which is divided by an isolation layer 203. Each of the transistors 200 may include a gate insulating layer 207 and a gate electrode 209 which are stacked on each other in the active region corresponding thereto, and junctions 205a and 205b which are formed in the active region at both sides of the gate electrode 209. The junctions 205a and 205b may include a conductivity type dopant for implementing transistors corresponding thereto. The junctions 205a and 205b may include at least one of an n type dopant and a p type dopant.

After the plurality of transistors 200 are formed, second connection structures 220 and the second insulation structure 211 may be formed. The second connection structures 220 may be coupled to the transistors 200 constituting the CMOS circuit. The second insulation structure 211 may cover the second connection structures 220 and the transistors 200.

The second insulation structure 211 may include two or more insulating layers 211A to 211D. The second connection structures 220 may be embedded in the second insulation structure 211. Each of the second connection structures 220 may include a plurality of conductive patterns 213, 215, 217, 219, 221, and 223. The second insulation structure 211 and the second connection structures 220 may not be limited to the example as shown in FIG. 6 but may vary.

The conductive patterns 213, 215, 217, 219, 221, and 223 which are included in each of the second connection structures 220 may include a second bonding metal 223 which has a surface exposed to the outside of the second insulation structure 211.

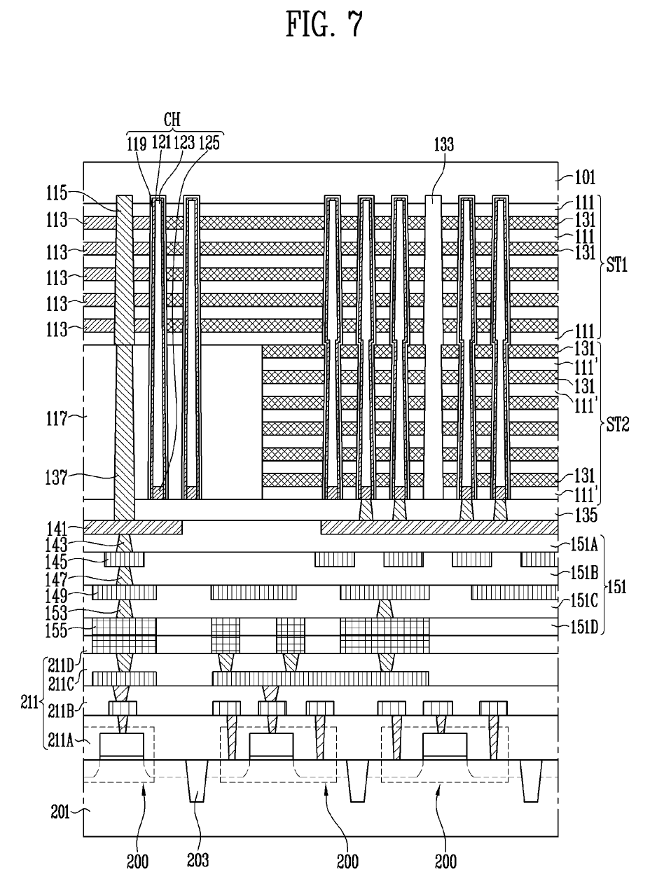

FIG. 7 is a cross-sectional diagram illustrating a process of bonding first connection structures and second connection structures to each other.

Referring to FIG. 7, the first substrate 101 and the second substrate 201 may be aligned with each other such that the first bonding metal 155 on the first substrate 101 and the second bonding metal 223 on the second substrate 201 may contact each other. The first bonding metal 155 and the second bonding metal 223 may include various metals, for example, copper.

The first bonding metal 155 and the second bonding metal 223 may be bonded to each other. After heat is applied to the first bonding metal 155 and the second bonding metal 223, the first bonding metal 155 and the second bonding metal 223 may be hardened. However, the present disclosure is not limited thereto. Various processes may be performed to connect the first bonding metal 155 and the second bonding metal 223 to each other.

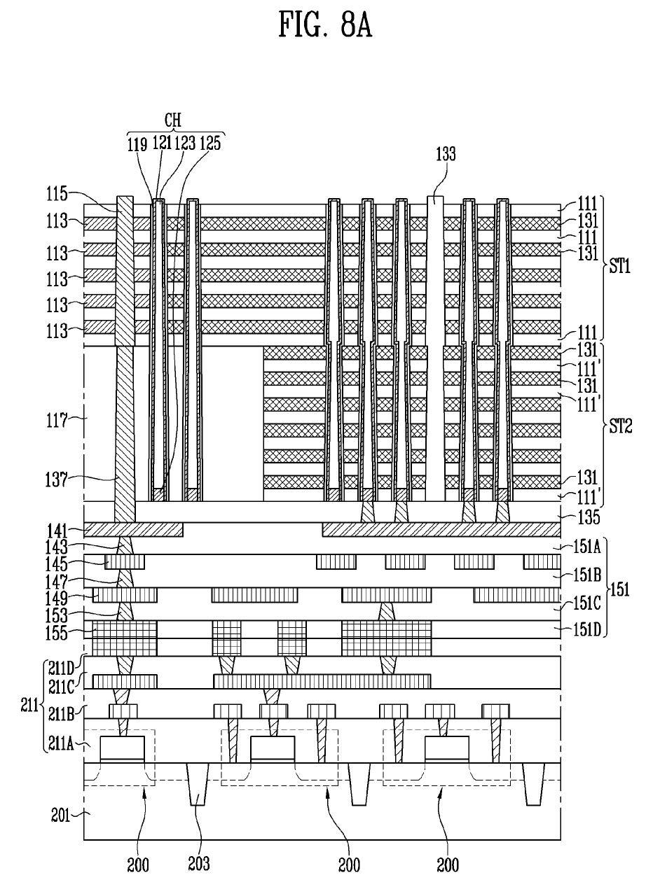

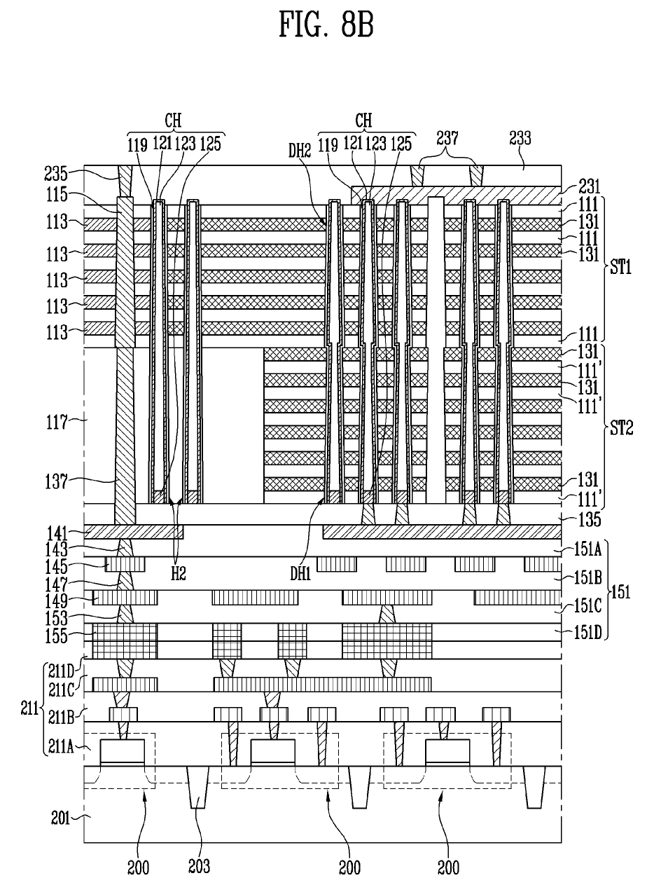

FIGS. 8A and 8B are cross-sectional diagrams illustrating processes of forming a source line structure coupled to a plurality of cell plugs on the first gate stack ST1.

Referring to FIG. 8A, the first substrate 101 as shown in FIG. 7 may be removed. As a result, the memory layer 119 and the channel layer 121 may protrude above an uppermost surface of the first gate stack ST1.

By performing an etch process, the memory layer 119 which protrudes above the uppermost surface of the first gate stack ST1 may be etched to expose the channel layer 121.

Subsequently, ion implantation may be performed to form a junction region by implanting a dopant into the channel layer 121 which serves as a channel of a source select transistor.

Referring to FIG. 8B, the source layer 231 may be formed to cover the uppermost surface of the first gate stack ST1 and the exposed surface of the channel layer 121, and the source layer 231 may be patterned. Therefore, the source layer 231 may be electrically and physically coupled to the channel layer 121 of the plurality of channel structures CH. The source layer 231 may be patterned so as not to be coupled to the channel structure CH formed in the first and second dummy holes DH1 and DH2 and the channel structure CH formed in the second holes H2 in the contact region.

According to an embodiment, the source layer 231 may include at least one layer. For example, the source layer 231 may include a first layer which includes a doped polysilicon layer, a second layer which includes titanium (Ti) or a titanium nitride (TiN) layer, and a third layer which includes tungsten.

The insulating layer 233 which covers the entire structure including the source layer 231 may be formed, and an opening through which portions of the first conductive layer 115 and the source layer 231 are exposed may be formed by etching the insulating layer 233. The contact 235 for a contact plug and the contact 237 for a source line may be formed by filling the opening with a conductive material.

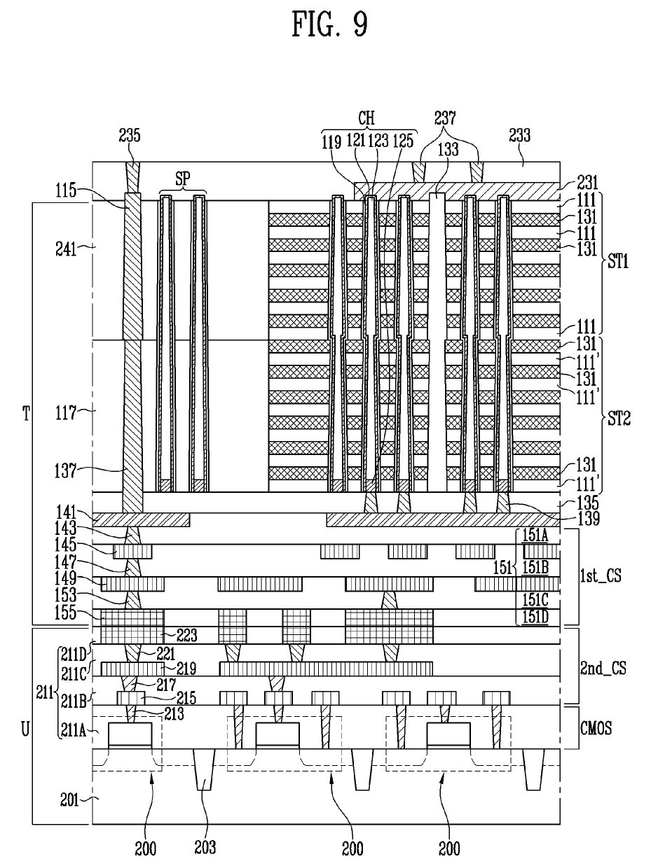

FIG. 9 is a cross-sectional view illustrating another embodiment of the memory cell array 20 shown in FIG. 1.

Referring to FIG. 9, the memory cell array may include the lower structure U and the upper structure T that are bonded to each other.

The upper structure T may include the first gate stack ST1 and the second gate stack ST2 which are stacked on each other in a vertical direction, the channel structures CH and the insulating pattern 133 which pass through the first gate stack ST1 and the second gate stack ST2 in the vertical direction, and the bit line 141 and the first connection structure 1st_CS which are arranged under the second gate stack ST2.

A region where the first gate stack ST1 and the second gate stack ST2 are stacked on top of each other and the channel structures CH pass through the first gate stack ST1 and the second gate stack ST2 may be defined as a cell region.

A critical dimension of the insulating pattern 133 which passes through the first gate stack ST1 and the second gate stack ST2 may be variable at a boundary region between the first gate stack ST1 and the second gate stack ST2. For example, the critical dimension of the insulating pattern 133 which passes through a lowermost surface of the first gate stack ST1 may be greater than that of the insulating pattern 133 which passes through an uppermost surface of the second gate stack ST2.

In addition, the critical dimension of the channel structure CH which passes through the first gate stack ST1 and the second gate stack ST2 may be variable at the boundary region between the first gate stack ST1 and the second gate stack ST2. For example, the critical dimension of the channel structure CH which passes through the lowermost surface of the first gate stack ST1 may be greater than the critical dimension of the channel structure CH which passes through the uppermost surface of the second gate stack ST2.

In the cell region, the first gate stack ST1 and the second gate stack ST2 may include the interlayer insulating layers 111 and 111’ and the conductive patterns 131. Each of the conductive patterns 131 may include various conductive materials such as a doped silicon layer, a metal layer, a metal silicide layer, and a barrier layer, and two or more types of conductive materials. For example, each of the conductive patterns 131 may include tungsten and a titanium nitride (TiN) layer which surrounds the surface of tungsten. Tungsten may be a low-resistance metal and reduce the resistance of the conductive patterns 131. The titanium nitride (TiN) layer may be a barrier layer and prevent a direct contact between the interlayer insulating layers 111 and 111’.

A conductive pattern adjacent to the bit line 141, among the conductive patterns 131, may serve as the drain select line DSL1 or DSL2 as shown in FIG. 2. According to another embodiment, two or more conductive patterns which are adjacent to the bit line 141 and successively stacked on top of each other may serve as drain select lines. A conductive pattern adjacent to a source layer 231, among the conductive patterns 131, may serve as the source select line SSL as shown in FIG. 2. According to another embodiment, two or more conductive patterns which are adjacent to the source layer 231 and successively stacked on top of each other may serve as source select lines. Conductive patterns which are adjacent to each other in a vertical direction and are arranged between a drain select line and a source select line may serve as the word lines WL1 to WLn as shown in FIG. 2.

The channel structure CH may pass through the first gate stack ST1 and the second gate stack ST2 in the vertical direction. The channel structure CH may be formed as a hollow type. The channel structure CH may include the core insulating layer 123 which fills a central region, the doped semiconductor layer 125 which is located under the core insulating layer 123, the channel layer 121 which surrounds sidewall surfaces of the core insulating layer 123 and the doped semiconductor layer 125 and an upper surface of the core insulating layer 123, and the memory layer 119 which surrounds an outer wall of the channel layer 121. The channel layer 121 may serve as a channel region of a cell string corresponding thereto. The channel layer 121 may include a semiconductor material. The memory layer 119 may include a tunnel isolation layer which surrounds the outer wall of the channel layer 121, a data storage layer which surrounds an outer wall of the tunnel isolation layer, and a blocking insulating layer which surrounds an outer wall of the data storage layer.

The bit line 141 may be arranged under the second gate stack ST2. The bit line 141 may be coupled to the channel structure CH through the contacts 139 which pass through the insulating layer 135. The bit line 141 may be separated from the second substrate 201 by the first insulation structure 151 and the second insulation structure 211.

The first connection structure 1st_CS may include the first insulation structure 151 and the first connection structures 143, 145, 147, 149, 153, and 155 formed in the first insulation structure 151. The first connection structures 143, 145, 147, 149, 153, and 155 may include various conductive patterns. The first insulation structure 151 may include two or more insulating layers 151A to 151D which are stacked on top of each other between the bit line 141 and the second insulation structure 211.

The source layer 231, the contact 235 for a contact plug, and the contact 237 for a source line may be arranged over the upper structure T. The source layer 231 may electrically and physically contact the channel layers 121 of the channel structures CH which protrude above the first gate stack ST1. The source layer 231 and the first gate stack ST1 may be covered by the insulating layer 233. The contact 237 for a source line may pass through the insulating layer 233 to be coupled to the source layer 231.

A plurality of interlayer insulating layers 241 and 117 may be stacked on each other in the contact region adjacent to the cell region. A region where the plurality of support structures SP and the contact plugs are arranged may be defined as a contact region. The interlayer insulating layer 117 may be arranged under the interlayer insulating layer 241. The upper structure T in the contact region may include the plurality of support structures SP which pass through the plurality of interlayer insulating layer 241 and 117. The plurality of support structures SP may include the same components as the channel structures. In addition, the upper structure T in the contact region may include the first conductive layer 115 and the second conductive layer 137 which pass through the plurality of interlayer insulating layers 241 and 117 in the vertical direction. The first conductive layer 115 and the second conductive layer 137 may be electrically coupled to each other and defined as a contact plug. A critical dimension of the first conductive layer 115 may be greater than that of the second conductive layer 137 in a region where the first conductive layer 115 and the second conductive layer 137 contact each other.

The lower structure U may include the CMOS circuit structure CMOS which includes the plurality of transistors 200 formed on the substrate SUB and the second connection structure 2nd_CS which is formed on the CMOS circuit structure CMOS. The isolation layer 203 may be disposed in the substrate SUB and separate junctions of the plurality of transistors 200 from each other.

The second connection structure 2nd_CS may include the second insulation structure 211 which is formed on the substrate SUB and the second connection structures 213, 215, 217, 219, 221, and 223 which are formed in the second insulation structure 211. Each of the second connection structures 213, 215, 217, 219, 221, and 223 may be embedded in the second insulation structure 211. The second insulation structure 211 may include two or more insulating layers 211A to 211D which are stacked sequentially.

The upper structure T and the lower structure U may be adhered to each other by a bonding process. For example, exposed conductive patterns 155 of the first connection structure 1st_CS of the upper structure T and exposed conductive patterns 223 of the second connection structure 2nd_CS of the lower structure U may oppose each other and be bonded to each other. The conductive patterns 155 and the conductive patterns 223 may be defined as bonding metal.

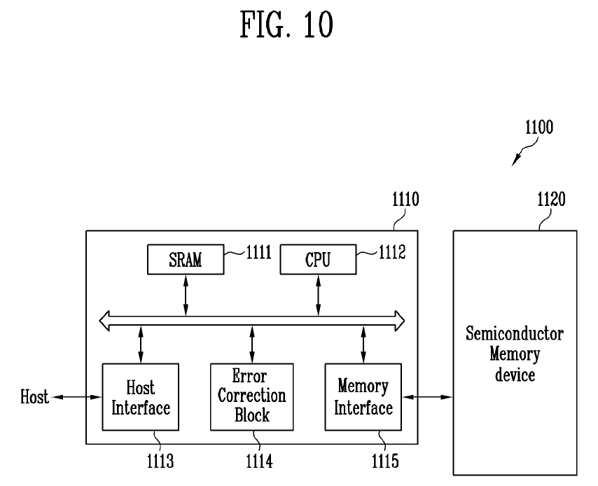

FIG. 10 is a block diagram illustrating a configuration of a memory system 1100 according to an embodiment of the present disclosure.

Referring to FIG. 10, the memory system 1100 includes a semiconductor memory device 1120 and a memory controller 1110.

The semiconductor memory device 1120 may be a multi-chip package which includes a plurality of flash memory chips. The semiconductor memory device 1120 may be the semiconductor memory device as described above with reference to FIGS. 1 to 4.

The memory controller 1110 may be configured to control the semiconductor memory device 1120, and may include static random access memory (SRAM) 1111, a central processing unit (CPU) 1112, a host interface 1113, an error correction block 1114, and a memory interface 1115. The SRAM 1111 may serve as operation memory of the CPU 1112, the CPU 1112 may perform an overall control operation for data exchange of the memory controller 1110, and the host interface 1113 may include a data exchange protocol of a host connected to the memory system 1100. In addition, the error correction block 1114 may detect and correct an error included in data read from the semiconductor memory device 1120, and the memory interface 1115 may perform interfacing with the semiconductor memory device 1120. In addition, the memory controller 1110 may further include read only memory (ROM) that stores code data for interfacing with the host.

The memory system 1100 may be a memory card or a solid state disk (SSD) into which the semiconductor memory device 1120 and the memory controller 1110 are integrated. For example, when the memory system 1100 serves as the SSD, the memory controller 1110 may communicate with an external device (e.g., a host) through one of the interface protocols including Universal Serial Bus (USB), MultiMedia Card (MMC), Peripheral Component Interconnection-Express (PCI-E), Serial Advanced Technology Attachment (SATA), Parallel Advanced Technology Attachment (PATA), Small Computer System Interface (SCSI), Enhanced Small Disk Interface (ESDI), and Integrated Drive Electronics (IDE).

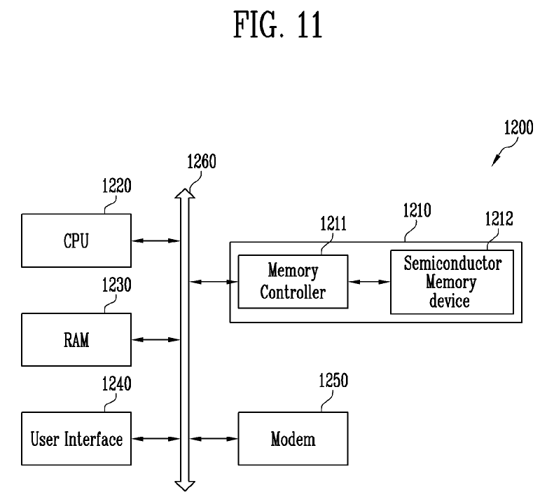

FIG. 11 is a block diagram illustrating a configuration of a computing system 1200 according to an embodiment of the present disclosure.

Referring to FIG. 11, the computing system 1200 may include a CPU 1220, random access memory (RAM) 1230, a user interface 1240, a modem 1250, and a memory system 1210 which are electrically connected to a system bus 1260. In addition, when the computing system 1200 is a mobile device, a battery for supplying an operating voltage to the computing system 1200 may be further included. In addition, an application chipset, an image processor, a mobile DRAM, and the like may be further included.

According to the present disclosure, an etch process of forming a cell plug and a slit and a process of filling a conductive material therein may be performed together during a process of forming a contact plug passing through a lower stacked structure. Accordingly, an additional support structure may not be formed, and an etch depth may be reduced during a slit etching process.

It will be apparent to those skilled in the art that various modifications can be made to the above-described embodiments of the present teachings without departing from the spirit or scope of the appended claims. Thus, it is intended that the present teachings cover all such modifications provided they come within the scope of the appended claims and their equivalents.

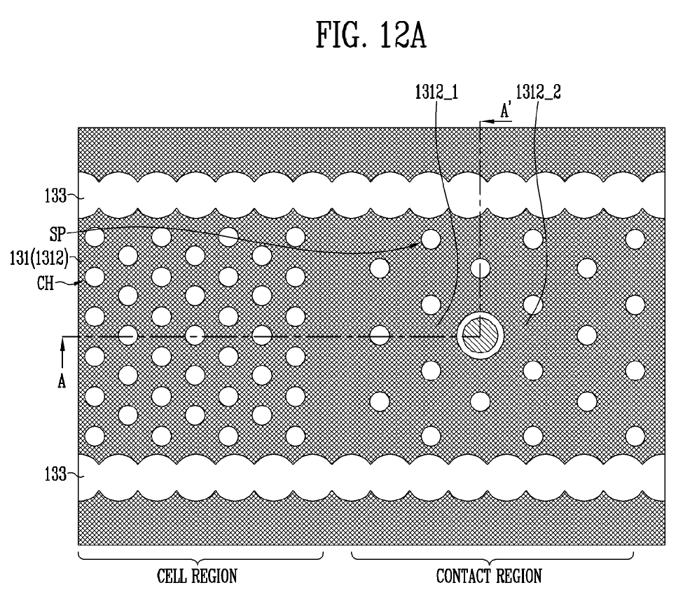

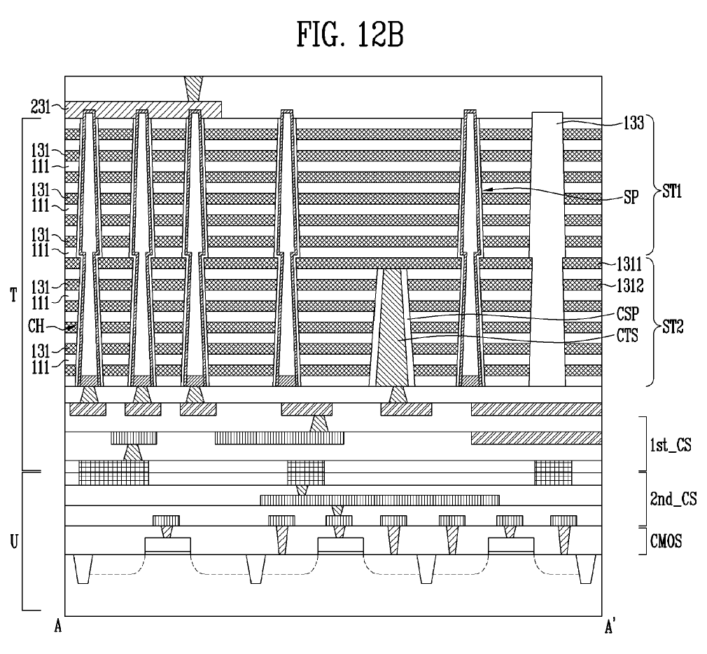

FIGS. 12A and 12B are diagrams illustrating a semiconductor device according to some embodiments. FIG. 12B is a cross-sectional view taken along line A-A' of FIG. 12A. The semiconductor memory devices according to FIGS. 12A and 12B may be similar to the semiconductor memory devices according to FIGS. 3 and 4, except as described below.

Referring to FIGS. 12A and 12B, conductive patterns 131 may extend into a contact region. The conductive patterns 131 may include a first conductive pattern 1311 and a second conductive pattern 1312. The first and second conductive patterns 1311, 131) may overlap each other. The second conductive pattern 1312 may be disposed over the first conductive pattern 1311. Throughout the specification, the term "over" may include "under" the semiconductor memory device, i.e., flipping the semiconductor memory device upside down.

A contact structure CTS penetrating the second conductive pattern 1312 and connected to the first conductive pattern 1311 may be provided. The contact structure CTS may include a conductive material. The lower surface of the contact structure CTS may directly be in contact with the first conductive pattern 1311. A critical dimension of the lower surface of the contact structure CTS may be smaller than a critical dimension of the upper surface of the contact structure CTS. The contact structure CTS may connect at least one of the conductive patterns 131 and the first wiring array 141, FIG. 4.

The second conductive pattern 1312 may surround the contact structure CTS. The second conductive pattern 1312 may include a first portion 1312_1 and a second portion 1312_2 that are spaced apart from each other with the contact structure CTS disposed therebetween. A contact spacer CSP may be provided between the second conductive pattern 1312 and the contact structure CTS. The contact spacer CSP may include an insulating material. For example, the contact spacer CSP may include an oxide.

The contact structure CTS may be disposed between a plurality of support structures SP. The contact structure CTS may be positioned between a pair of insulating patterns 133. The insulating patterns 133 may correspond to slit patterns. In some embodiments, the second stacked structure ST2 on the contact area may not include a step-like structure.

Manufacturing a semiconductor memory device according to FIGS. 12A and 12B may comprise forming a contact hole penetrating the conductive patterns 131 and the interlayer insulating layers 111. Forming the contact hole may include exposing a sidewall of the second conductive pattern 1312 and an upper surface of the first conductive pattern 1311. A preliminary contact spacer may be formed within the contact hole. By etching the preliminary contact spacer, the upper surface of the first conductive pattern 1311 may be exposed. The etched preliminary contact spacer may be defined as a contact spacer CSP. A contact structure CTS may be formed on the contact spacer CSP and the first conductive pattern 1311.

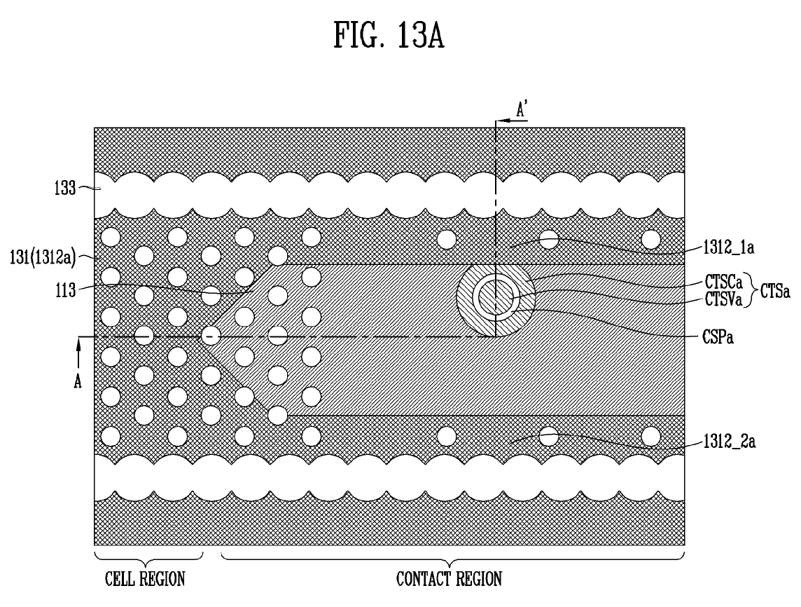

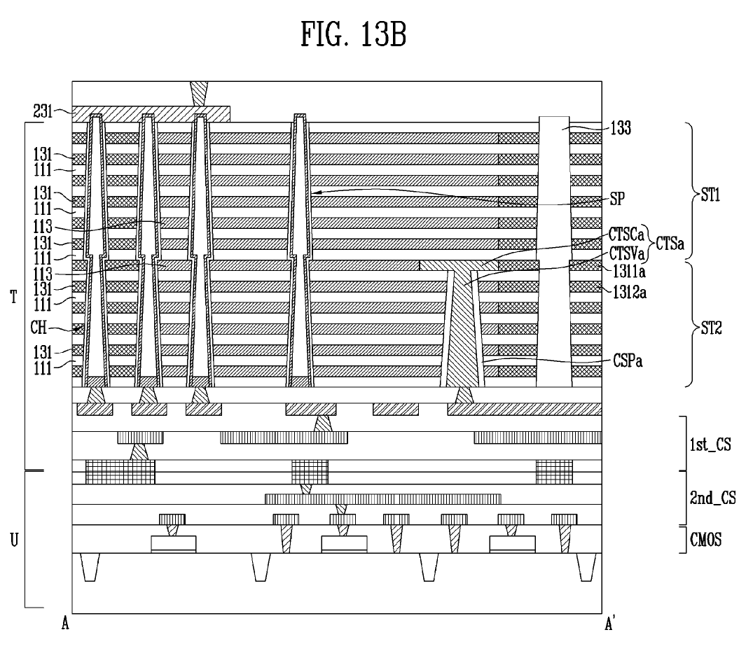

FIGS. 13A and 13B are diagrams illustrating semiconductor memory devices according to some embodiments. The semiconductor memory devices according to FIGS. 13A and 13b may be similar to the semiconductor memory devices according to FIGS. 12A and 12B, except as described below.

Referring to FIGS. 13A and 13B, second material layers 113 may be disposed on the sidewalls of each of the conductive patterns 131. The conductive pattern 131 may include a first portion and a second portion spaced apart by the second material layer 113. For example, the second conductive pattern 1312a may include a first portion 1312_1a and a second portion 1312_2a spaced apart from each other with the second material layer 113 disposed therebetween.

A contact structure CTSa may be disposed between the first and second portions 1312_1a, 1312_2a of the second conductive pattern 1312a. The contact structure CTSa may extend vertically penetrating the second material layer 113. The contact structure CTSa may include a via portion CTSVa extending vertically, and a contact portion CTSCa extending from the via portion CTSVa. A critical dimension of the contact portion CTSCa of the contact structure CTSa may be larger than a critical dimension of a top surface of the via portion CTSVa.

The contact portion CTSCa of the contact structure CTSa may directly be in contact with a sidewall of the first conductive pattern 1311a. The via portion CTSVa of the contact structure CTSa may penetrate the second material layers 113. A contact spacer CSPa may surround the via portion CTSVa of the contact structure CTSa. The contact spacer CSPa may be disposed between the contact structure CTSa and the second material layer 113. The contact spacer CSPa may include a material having an etch selectivity with respect to the second material layer 113. For example, the second material layer 113 may include a nitride, and the contact spacer CSPa may include an oxide.

Manufacturing a semiconductor memory device according to FIGS. 13A and 13B may comprise etching sidewalls of conductive patterns 131 through trenches, before forming insulating patterns 133. By etching the sidewalls of the conductive patterns 131, sidewalls of second material layers 113 may be exposed. A contact hole penetrating the second material layer 113 may be formed. A preliminary contact spacer may be formed within the contact hole. By etching the preliminary contact spacer, an upper surface of the second material layer 113 at the same level as the first conductive pattern 1311a may be exposed. An upper surface of the second material layer 113 at the same level as the first conductive pattern 1311a may be selectively etched. By selectively etching the second material layer 113, a sidewall of the first conductive pattern 1311a may be exposed. A contact structure CTSa may be formed on the exposed side wall of the first challenge pattern 1311a.

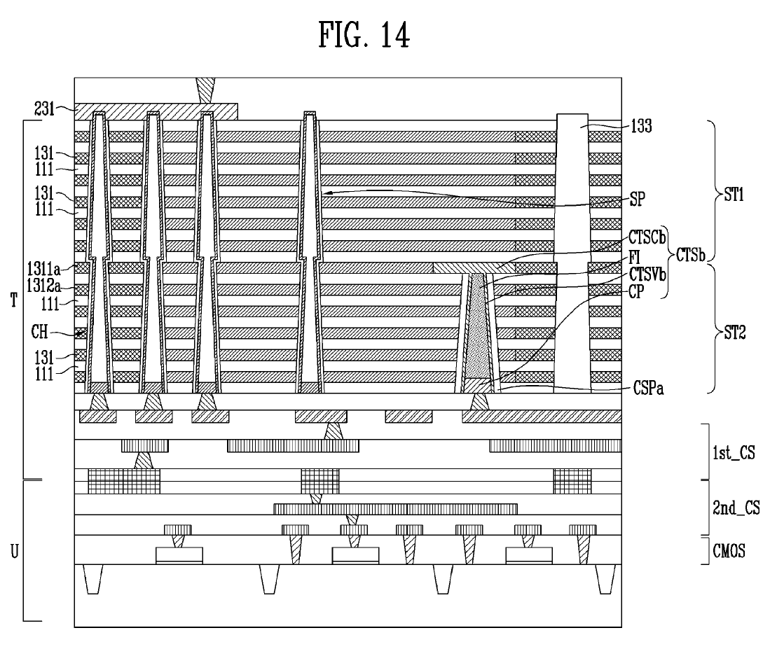

FIG. 14 is a diagram illustrating a semiconductor memory device according to some embodiments. The semiconductor memory device according to FIG. 14 may be similar to the semiconductor memory device according to FIGS. 13A and 13B, except as described below.

Referring to FIG. 14, the contact structure CTSb may include a via portion CTSVb, a contact portion CTSCb, a filler insulating layer FI, and a capping layer CP. The filler insulating layer FI may include an insulating material. The filler insulating layer FI may fill the space between the via portion CTSVb and the capping layer CP of the contact structure CTSb. The filler insulating layer FI may be disposed in the via portion CTSVb, the capping layer CP, and the contact portion CTSCb of the contact structure CTSb. The via portion CTSVb of the contact structure CTSb may surround the filler insulating layer FI.

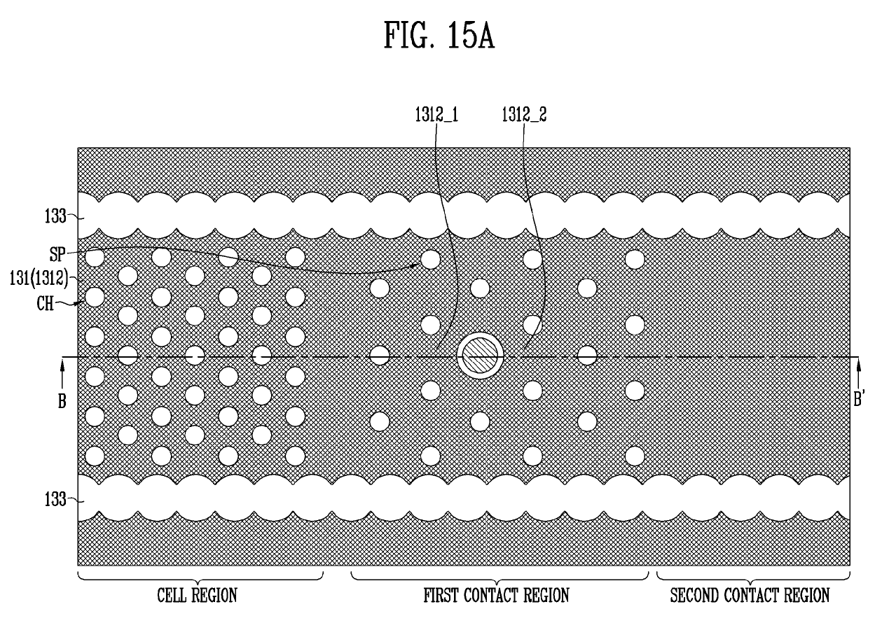

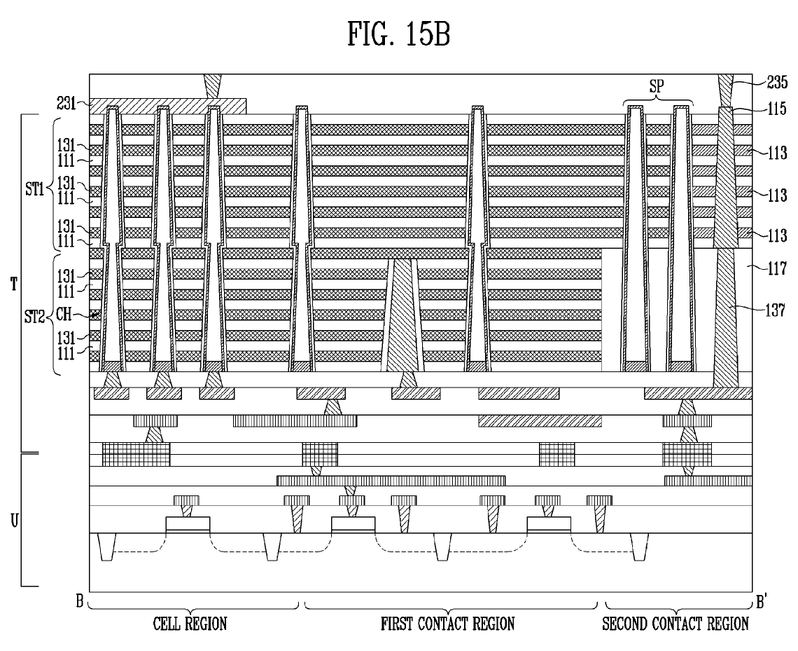

FIGS. 15A and 15B are diagrams illustrating semiconductor memory devices according to some embodiments. FIG. 15B is a cross-sectional view taken along line B-B' of FIG. 15A. The semiconductor memory devices according to FIGS. 15A and 15B may be similar to the semiconductor memory devices according to FIGS. 12A and 12B, except as described below.

Referring to FIGS. 15A and 15B, the semiconductor memory devices may include a first contact region and a second contact region. An interlayer insulating layer 117 may be provided in the second contact region. A support structure SP penetrating the first gate stack ST1 and the interlayer insulating layer 117 may be provided. A first conductive layer 115 penetrating the first gate stack ST1 and a second conductive layer 137 penetrating the interlayer insulating layer 117 may be provided, respectively. The support structure SP may penetrate the conductive patterns 131 of the first gate stack ST1.

Manufacturing a semiconductor memory device according to FIGS. 15A and 15B may include forming a first stack ST1, forming a first conductive layer 115 penetrating the first stack ST1, forming a second stack structure ST2 covering the first stack ST1 and the first conductive layer 115, forming a mask pattern covering the cell region and the first contact region on the first and second stack structures ST1, ST2, etching the second stack structure within the second contact region using the mask pattern, forming an interlayer insulating layer 117, forming a second conductive layer 137 penetrating the interlayer insulating layer 117, and forming a support structure SP penetrating the interlayer insulating layer 117 and the first stack structure.

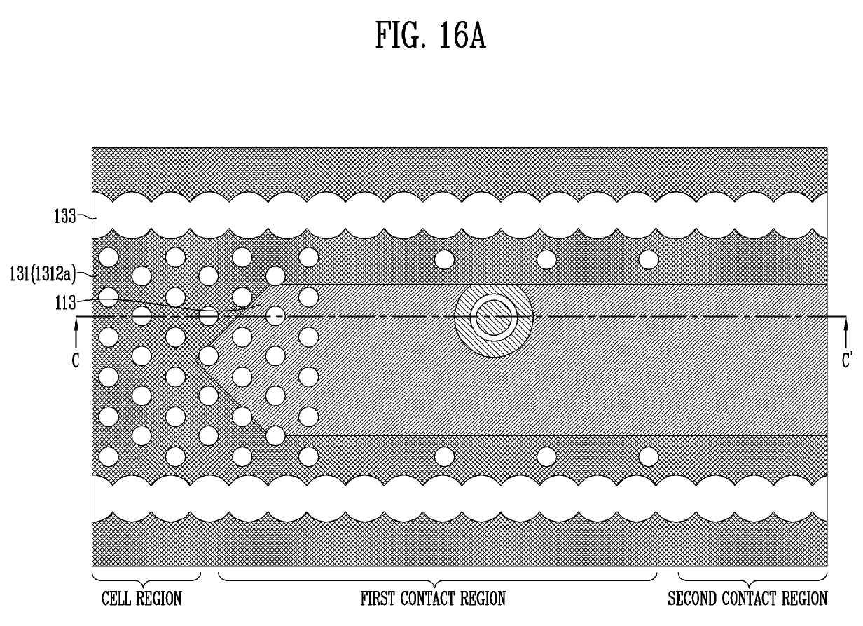

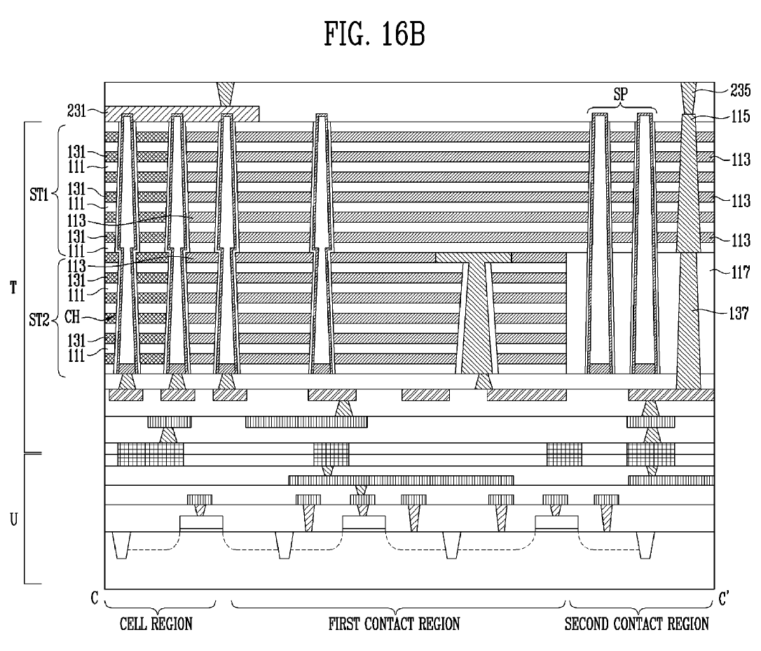

FIGS. 16A and 16B are diagrams illustrating semiconductor memory devices according to some embodiments. FIG. 16B is a cross-sectional view taken along line C-C' of FIG. 16A. The semiconductor memory devices according to FIGS. 16A and 16B may be similar to the semiconductor memory devices according to FIGS. 13A and 13B, except as described below.

Referring to FIGS. 16A and 16B, the semiconductor memory devices may include a first contact region and a second contact region. An interlayer insulating layer 117 may be provided in the second contact region. A support structure SP penetrating the first gate stack ST1 and the interlayer insulating layer 117 may be provided. A first conductive layer 115 penetrating the first gate stack ST1 and a second conductive layer 137 penetrating the interlayer insulating layer 117 may be provided, respectively. The support structure SP may penetrate the interlayer insulating layers 111, 113 of the first gate stack ST1. The first conductive layer 115 may penetrate the interlayer insulating layers 111, 113 of the first gate stack ST1. Manufacturing a semiconductor memory device according to FIGS. 16a and 16b may include forming a first stacked structure ST1, forming a first conductive layer 115 penetrating the first stacked structure ST1, forming a second stacked structure ST2 covering the first stacked structure ST1 and the first conductive layer 115, forming a mask pattern covering a cell region and a first contact region on the first and second stacked structures ST1, ST2, etching the second stacked structure in the second contact region using the mask pattern, forming an interlayer insulating layer 117, forming a second conductive layer 137 penetrating the interlayer insulating layer 117, and forming a support structure SP penetrating the interlayer insulating layer 117 and the first stacked structure.

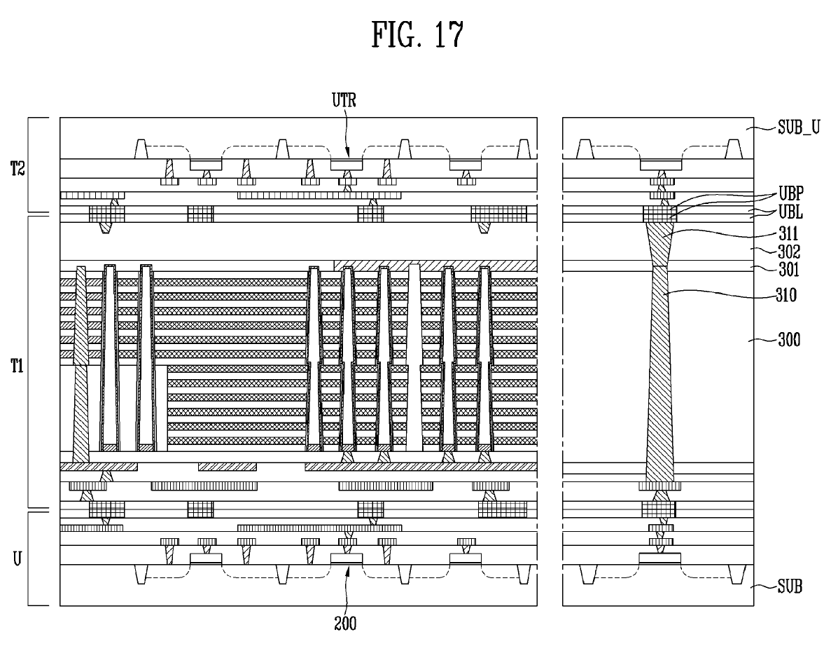

FIG. 17 is a diagram illustrating a semiconductor memory device according to some embodiments. The semiconductor memory device according to FIG. 17 may be similar to the semiconductor memory device according to FIG. 4, except as described below.

Referring to FIG. 17, a first upper structure T1 and a second upper structure T2 may be provided on a lower structure U. The first upper structure T1 may be similar to the upper structure T of FIG. 4. An upper bonding layer UBL and an upper bonding pad UBP may be provided in the upper portion of the first upper structure T1 and the lower portion of the second upper structure T2. The upper bonding pad UBP and the upper bonding layer UBL may bond the first and second upper structures T1, T2 to each other.

The second upper structure T2 may include an upper substrate SUB_U and an upper transistor UTR in the upper substrate SUB_U. The first upper structure T1 may include a first connection insulating layer 300, a second connection insulating layer 301, and a third connection insulating layer 302. A first connection contact 310 penetrating the first connection insulating layer 300 may be provided. A connection contact 311 penetrating the third connection insulating layer 302 may be provided.

The peripheral circuit may include an upper transistor UTR. The upper transistor UTR may be connected to the lower structure U through an upper bonding pad UBP, a first connection contact 310, and a second connection contact 311. The upper transistor UTR may be electrically connected to the transistor 200. Manufacturing a semiconductor memory device according to FIG. 17 may include forming a first wafer including a lower structure U, forming a second wafer including a first upper structure T1, bonding the first and second wafers to each other, forming a third wafer including a second upper structure T2, and bonding the second and third wafers to each other.

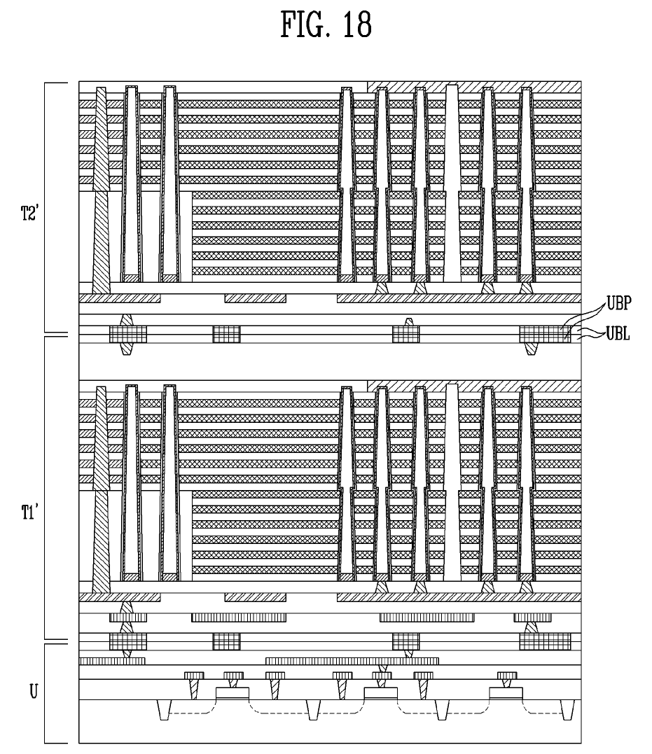

FIG. 18 is a diagram illustrating a semiconductor memory device according to some embodiments. The semiconductor memory device according to FIG. 18 may be similar to the semiconductor memory device according to FIG. 4, except as described below.

Referring to FIG. 18, the semiconductor memory device may include a first upper structure T1' and a second upper structure T2' on a lower structure U. Each of the first and second upper structures T1', T2' may be similar to the upper structure T1 of the semiconductor memory device according to FIG. 4. An upper bonding layer UBL and an upper bonding pad UBP may be provided above the first upper structure T1' and below the second upper structure T2'. The first and second upper structures T1', T2' may be bonded to each other by the upper bonding layer UBL and the upper bonding pad UBP. Manufacturing a semiconductor memory device according to FIG. 18 may include forming a first wafer including a lower structure U, forming a second wafer including a first upper structure T1', bonding the first and second wafers to each other, forming a third wafer including a second upper structure T2', and bonding the second and third wafers to each other.

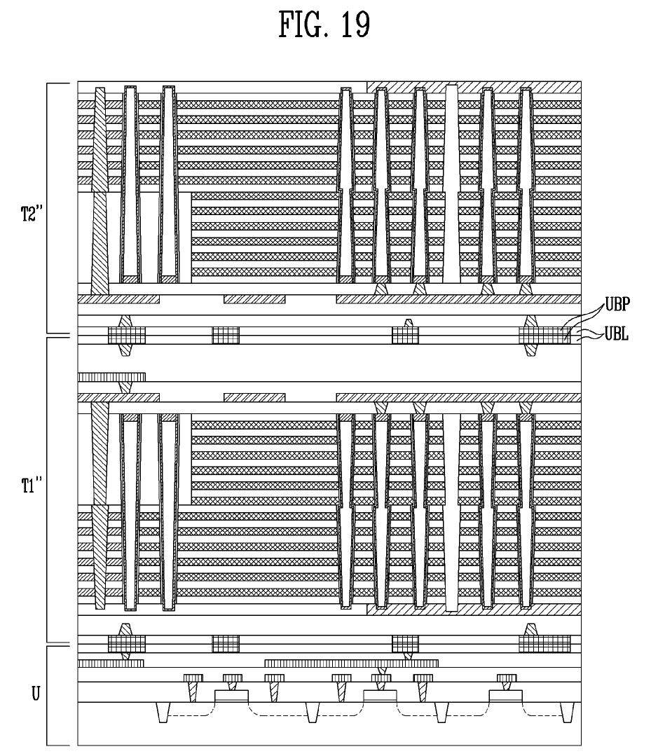

FIG. 19 is a diagram illustrating a semiconductor memory device according to some embodiments. The semiconductor memory device according to FIG. 19 may be similar to the semiconductor memory device according to FIG. 18, except as described below.

Referring to FIG. 19, a first upper structure T1'' and a second upper structure T2'' on a lower structure U may be provided. The first upper structure T1'' may be similar to the first upper structure T1' according to FIG. 18, flipped upside down.

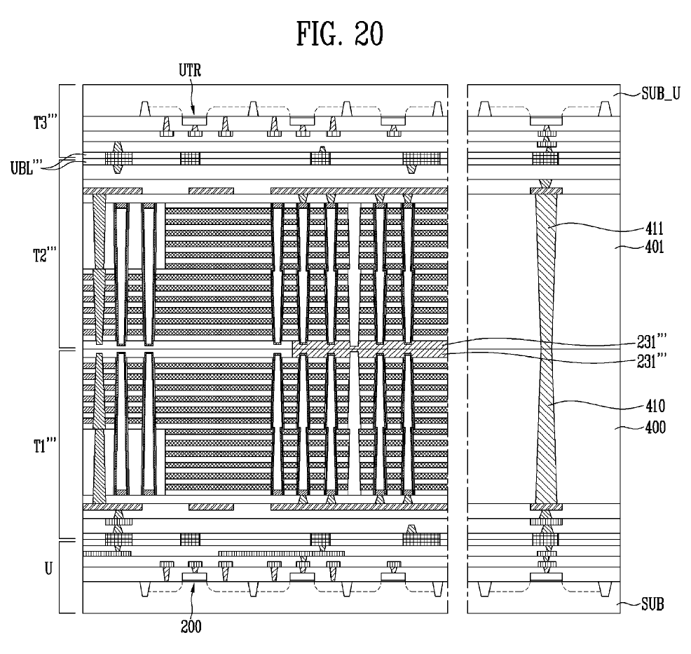

FIG. 20 is a diagram illustrating a semiconductor memory device according to some embodiments. The semiconductor memory device according to FIG. 20 may be similar to the semiconductor memory device according to FIG. 18, except as described below.

Referring to FIG. 20, a first upper structure T1''', a second upper structure T2''', and a third upper structure T3''' may be provided on a lower structure U. The second upper structure T2'' may be similar to the second upper structure T2' of FIG. 18, flipped upside down.

The source layer 231''' of the first upper structure T1''' may be bonded to the source layer 231''' of the second upper structure T2'''. An upper bonding layer UBL''' may be provided in the upper portion of the second upper structure T2''' and the lower portion of the third upper structure T3'''. The second and third upper structures T2''', T3''' may be bonded to each other by the upper bonding layer UBL'''. The third upper structure T3''' may include an upper transistor UTR''' and an upper substrate SUB_U.

The first upper structure T1''' may include a first connection insulating layer 400. The second upper structure T2''' may include a second connection insulating layer 401. A first connection contact 410 penetrating the first connection insulating layer 400 and a second connection contact 411 penetrating the second connection insulating layer 401 may be provided. The first and second connection contacts 410, 411 may connect the third upper structure T3''' and the lower structure U.

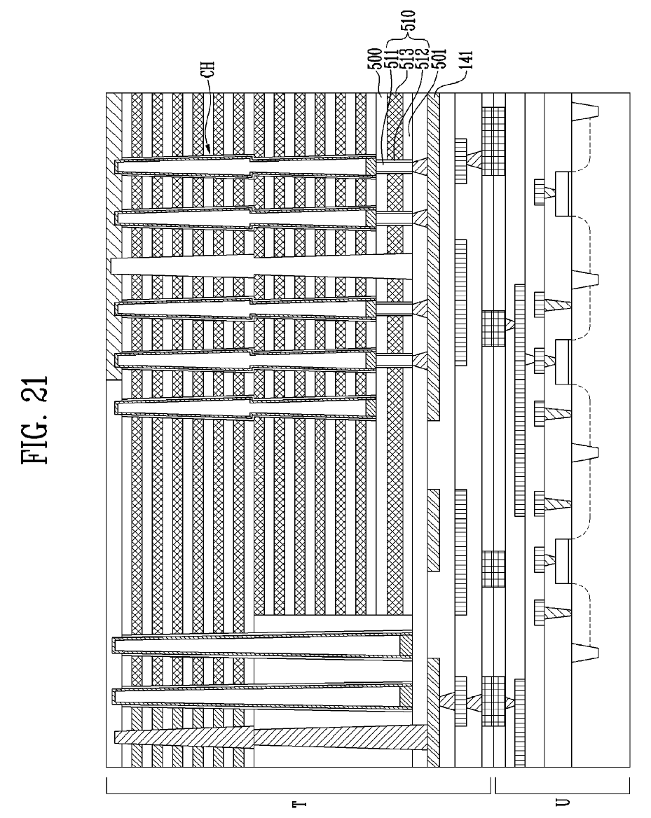

FIG. 21 is a diagram illustrating a semiconductor memory device according to some embodiments. The semiconductor memory device according to FIG. 21 may be similar to the semiconductor memory device according to FIG. 4, except as described below.

The upper structure T may include a first lower interlayer insulating layer 500, a second lower interlayer insulating layer 501, and a lower gate electrode 513 between the first and second lower interlayer insulating layers 500, 501. A lower channel layer 511 and a lower gate insulating layer 512 penetrating the lower gate electrode 513 and the first and second lower interlayer insulating layers 500, 501 may be provided.

The lower channel layer 511 may include a semiconductor material. The lower channel layer 511 may connect the channel structure CH and the bit line 141. The lower channel layer 511, the lower gate insulating layer 512, and the lower gate electrode 513 may define a drain select transistor 510.

What is claimed is:

1. A semiconductor memory device, comprising:
a lower structure including a cell region and a contact region;
a first stacked structure including a first portion over the cell region of the lower structure and a second portion over the contact region of the lower structure; and
a second stacked structure stacked over the first portion of the first stacked structure,
wherein the first stacked structure includes at least one lower cell plug pattern extending in a vertical direction and a lower slit pattern extending in the vertical direction,
wherein the second stacked structure includes at least one upper cell plug pattern extending in the vertical direction and directly contacting an upper surface of the at least one lower cell plug pattern, and an upper slit pattern extending in the vertical direction and directly contacting an upper surface of the lower slit pattern,
wherein a lower surface of the upper slit pattern contacting the upper surface of the lower slit pattern has a lower critical dimension than the upper surface of the lower slit pattern, and
wherein the first stacked structure further includes:
a first conductive pattern;
a second conductive pattern over the first conductive pattern, wherein the second conductive pattern includes a first portion and a second portion; and
a contact structure connected to the first conductive pattern and disposed between the first and second portions of the second conductive pattern.

2. The semiconductor memory device of claim 1, wherein the first portion of first stacked structure includes:
first material layers and second material layers alternately disposed over a surface of the interlayer insulating layer facing away from the lower structure; and
a first conductive layer extending through the first material layers and the second material layers of the first stack structure.

3. The semiconductor memory device of claim 1, wherein the contact structure penetrates the second conductive pattern.

4. The semiconductor memory device of claim 1, wherein the first stacked structure and the second stacked structure formed in the cell region further include a dummy cell plug extending in the vertical direction.

5. The semiconductor memory device of claim 4, wherein the dummy cell plug comprises:
a lower dummy plug pattern included in the first stacked structure; and
an upper dummy plug pattern included in the second stacked structure, the upper dummy plug pattern contacting the lower dummy plug pattern.

6. The semiconductor memory device of claim 5, wherein the lower surface of the upper dummy plug pattern contacting the lower dummy plug pattern has a lower critical dimension than the upper surface of the lower dummy plug pattern.

7. The semiconductor memory device of claim 1, wherein the contact structure includes a via portion and a contact portion extending from the via portion.

8. The semiconductor memory device of claim 7, wherein the contact portion of the contact structure is directly contact with the first conductive pattern.

9. The semiconductor memory device of claim 8, wherein the via portion of the contact structure is spaced apart from the first conductive pattern.

10. A semiconductor memory device, comprising:
a lower structure including a cell region and a contact region;
a first stacked structure including a first portion over the cell region of the lower structure and a second portion over the contact region of the lower structure; and
a second stacked structure stacked over the first portion of the first stacked structure,
wherein the first stacked structure includes at least one lower cell plug pattern extending in a vertical direction and a lower slit pattern extending in the vertical direction,
wherein the second stacked structure includes at least one upper cell plug pattern extending in the vertical direction and directly contacting an upper surface of the at least one lower cell plug pattern, and an upper slit pattern extending in the vertical direction and directly contacting an upper surface of the lower slit pattern,
wherein a lower surface of the upper slit pattern contacting the upper surface of the lower slit pattern has a lower critical dimension than the upper surface of the lower slit pattern,
wherein the first stacked structure further includes:
a first conductive pattern;
a second conductive pattern over the first conductive pattern;
a contact structure connected to the first conductive pattern; and
a contact spacer between the second conductive pattern and the contact structure, and
wherein the contact spacer surrounds the first conductive pattern.

11. The semiconductor memory device of claim 10, wherein the contact spacer includes a dielectric material.

12. The semiconductor memory device of claim 11, wherein the second conductive pattern surrounds the contact spacer.

13. The semiconductor memory device of claim 11, wherein the contact structure connected to the sidewall of the first conductive pattern.

14. The semiconductor memory device of claim 11, wherein the first stacked structure and the second stacked structure formed in the cell region further include a dummy cell plug extending in the vertical direction.

15. The semiconductor memory device of claim 14, wherein the dummy cell plug comprises:
a lower dummy plug pattern included in the first stacked structure; and
an upper dummy plug pattern included in the second stacked structure, the upper dummy plug pattern contacting the lower dummy plug pattern.
